(19) United States
(12) Patent Application Publication
(10) Pub. No.: US 2026/0006344 A1
(43) Pub. Date: Jan. 1, 2026

(54) IMAGE SENSOR WITH STACKED COLOR FILTERS OR MULTI-STATE TUNABLE COLOR FILTER

(71) Applicant: Adeia Imaging LLC, San Jose, CA (US)

(72) Inventors: Ning Xu, Irvine, CA (US); Tao Chen, Palo Alto, CA (US); Serhad Doken, Bryn Mawr, PA (US); Jean-Yves Couleaud, Mission Viejo, CA (US)

(21) Appl. No.: 18/757,873

(22) Filed: Jun. 28, 2024

(51) Int. Cl. H04N 25/13; H01L 27/146; H04N 23/84

(52) U.S. Cl. CPC H04N 25/13; H04N 23/84; H04N 25/17; H10F 39/1825; H10F 39/8053

(57) ABSTRACT

An image sensor with one or more imaging sensor layers and/or one or more color filter layers is provided. Imaging sensor layers sense different combinations of wavelengths of light depending in part on filtered light passing through the color filter layers. The color filter layers, which can be tunable filters, plasmonic color filters or dielectric subwavelength grating filters, allow certain colors of light to pass through to the imaging sensor layers and block others. The image sensor is connected to control circuitry that measures the properties of light received at each imaging sensor layer, reconstructs the color components of each pixel of the imaging sensor layers based on these measurements, and generates full-color image data from the color components. Methods of manufacturing the image sensor are also provided using lithography and securing the layers in a sensor stack using a bonding substrate.

### FIELD OF THE DISCLOSURE

The present disclosure relates to digital imaging, such as for digital cameras, smartphones, extended reality headsets, medical imaging devices, and the like.

### SUMMARY

Digital color cameras typically use a single image sensor overlaid with a color filter array (CFA) to capture color information. The most widely used CFA is the Bayer pattern, which has a repeating 2×2 pattern of red, green, and blue filters. Each pixel only captures one of the three color components, so the missing color values at each pixel need to be estimated to reconstruct the full-color image using a process known as demosaicing. However, demosaicing has several disadvantages, including loss of resolution and detail due to interpolation, potential for artifacts like zipper effects and moiré patterns, and color channel misalignment in the presence of high-frequency details.

Some imaging cameras employ a multi-sensor design with separate image sensors dedicated to capturing red, green, and blue color channels, avoiding the need for demosaicing by directly sampling all three colors at every pixel location. One image sensor design uses a prism or other beam-splitting optics to separate the incoming light onto three separate monochrome image sensors with broadband RGB filters. However, this multi-sensor design increases system complexity due to the need for precise alignment of multiple sensors and intricate optics, leads to a larger overall form factor, results in higher costs due to the use of prism or beam-splitter components, and can cause parallax errors and stitching issues when combining the images captured by slightly offset sensors.

A transparent diffractive-filter array-based method was proposed to replace the Bayer pattern and uses a computational method to reconstruct the RGB image. However, this method shows color distortions and blurring at the boundaries due to crosstalk effects.

Transparent image sensors have been proposed; however, in the proposed approaches, transparent image sensors have not been integrated into imaging devices. Separately, tunable color filters have been proposed; however, in the proposed approaches, practical implementations have not been developed.

To help address the limitations and problems of these and other approaches, several embodiments of an image sensor are provided with various combinations of features. In some embodiments, an image sensor comprises three imaging sensor layers and two color filter layers. For example, a first imaging sensor layer is not transparent and senses filtered green light. Also, for example, second and third imaging sensor layers are transparent, with the second layer sensing filtered red and green light, and the third layer sensing red, green, and blue light. Further, for example, a first color filter layer, positioned or disposed over the first imaging sensor layer, allows green light to pass through and blocks red light. Still further, for example, a second color filter layer, positioned or disposed over the second imaging sensor layer, allows red and green light to pass through and blocks blue light. Further still, for example, the color filter layers can comprise a plasmonic color filter or a dielectric subwavelength grating filter.

In some embodiments, the image sensor is connected with control circuitry that measures the properties of light transmitted to or impinging on each imaging sensor layer. For example, the control circuitry reconstructs the red, green, and blue components of each pixel of an image sensed by the image sensor. Also, for example, the control circuitry reconstructs the red, green, and blue components of each pixel to generate full-color pixels, and such color pixels are generally combined together to generate a color image or image data, which may be output by a display. Further, for example, the color components are based on these measurements and/or a predetermined transmittance rate of each image sensor layer and/or each color filter layer. Still further, for example, the control circuitry then outputs these color components for each pixel.

In some embodiments, the image sensor includes multiple pixels, each pixel location corresponding to a combination of all the sensor and filter layers. For example, the sensor can be used in a configuration where the control circuitry reconstructs and outputs the color components based on the signals from each imaging sensor layer.

In some embodiments, a method of capturing an image is provided. For example, the method involves the image sensor described herein.

In some embodiments, a method of manufacturing is provided. For example, the method involves manufacturing the image sensor described herein. Also, for example, the layers are formed using lithography and secured in a sensor stack using a bonding substrate. Further, for example, bonding layers are provided between each imaging sensor layer and color filter layer.

In some embodiments, the image sensor described herein is incorporated with a camera, a smartphone, an extended reality device, or a medical imaging device.

In some embodiments, an image sensor comprises an imaging sensor layer and a tunable color filter layer. For example, the color filter layer has at least two states and can operate over at least two time periods. Also, for example, the image sensor is connected to control circuitry that alters the light transmission property of the tunable color filter layer between these states over the time periods.

In various embodiments, the tunable color filter layer can operate in two or three states over corresponding time periods. For example, the tunable color filter layer can, in some embodiments, be provided between two imaging sensor layers, or, in other embodiments, over an imaging sensor layer with another tunable color filter layer over the tunable color filter layer.

In some embodiments, in different states, the tunable color filter layer allows certain colors of light (e.g., red, green, or blue) to pass through to the imaging sensor layer and blocks others. For example, the sequence of these states can be operated in a specific order over the time periods.

In some embodiments, a method of capturing an image is provided. For example, the method involves sensing an image with the image sensor with the one or more tunable color filter layers described herein.

In some embodiments, a method of manufacturing is provided. For example, the method involves manufacturing the image sensor with the one or more tunable color filter layers described herein. For example, the imaging sensor layer and the tunable color filter layer are formed using lithography.

In some embodiments, the image sensor described herein with the one or more tunable color filter layers is incorporated with a camera, a smartphone, an extended reality device, or a medical imaging device.

Also provided is a device equipped with means for performing one or more of the above-referenced features. Further provided is a non-transitory, computer-readable medium with instructions that, when executed, perform one or more of the above-referenced features. Related processes, subprocesses, apparatuses, devices, techniques, and articles are also provided.

The present invention is not limited to the combination of the elements as listed herein and may be assembled in any combination of the elements as described herein. These and other capabilities of the disclosed subject matter will be more fully understood after a review of the following figures, detailed description, and claims.

### BRIEF DESCRIPTIONS OF THE DRAWINGS

The present disclosure, in accordance with one or more various embodiments, is described in detail with reference to the following figures. The drawings are provided for purposes of illustration only and merely depict non-limiting examples and embodiments. These drawings are provided to facilitate an understanding of the concepts disclosed herein and should not be considered limiting of the breadth, scope, or applicability of these concepts. It should be noted that for clarity and ease of illustration these drawings are not necessarily made to scale.

The embodiments herein may be better understood by referring to the following description in conjunction with the accompanying drawings, in which like reference numerals indicate identical or functionally similar elements, of which:

FIG. 1 depicts a camera device and its internal hardware components, in accordance with some embodiments of the disclosure;

FIG. 2A depicts a schematic diagram of an imaging sensor, in accordance with some embodiments of the disclosure;

FIG. 2B depicts an internal schematic diagram of an imaging sensor, in accordance with some embodiments of the disclosure;

FIG. 3 depicts a stacked sensor configuration using three imaging sensor layers and two color filter layers, in accordance with some embodiments of the disclosure;

FIG. 4 depicts a stacked sensor configuration using two imaging sensor layers and one dynamically tunable color filter layer, in accordance with some embodiments of the disclosure;

FIG. 5 depicts a stacked sensor configuration using one imaging sensor layer and two dynamically tunable color filter layers, in accordance with some embodiments of the disclosure;

FIG. 6 depicts a stacked sensor configuration using one imaging sensor layer and one dynamically tunable color filter layer, in accordance with some embodiments of the disclosure;

FIG. 7 depicts the components involved in processing image sensor data, in accordance with some embodiments of the disclosure;

FIG. 8 depicts a transmittance curve for different color filters, in accordance with some embodiments of the disclosure;

FIG. 9A depicts a diagram of the stacked sensor configuration using three imaging sensor layers and two color filter layers, in accordance with some embodiments of the disclosure;

FIG. 9B depicts a stacked sensor configuration highlighting the components of light detected at each imaging sensor layer, in accordance with some embodiments of the disclosure;

FIG. 10 depicts a stacked sensor including the bonding material in-between each layer of the stacked sensor, in accordance with some embodiments of the disclosure;

FIG. 11A depicts a diagram of a stacked sensor configuration using two imaging sensor layers and one dynamically tunable color filter layer tuned to a first color state at a first time, in accordance with some embodiments of the disclosure;

FIG. 11B depicts a diagram of a stacked sensor configuration using two imaging sensor layers and one dynamically tunable color filter layer tuned to a second color state at a second time, in accordance with some embodiments of the disclosure;

FIG. 11C shows a chart detailing a first order in which a tunable color filter layer may switch between color states at different times, in accordance with some embodiments of the disclosure;

FIG. 11D shows a chart detailing a second order in which a tunable color filter layer may switch between color states at different times, in accordance with some embodiments of the disclosure;

FIG. 12A depicts a diagram of a stacked sensor configuration using one imaging sensor layer and two dynamically tunable color filter layers tuned to a first color state at a first time, in accordance with some embodiments of the disclosure;

FIG. 12B depicts a diagram of a stacked sensor configuration using one imaging sensor layer and two dynamically tunable color filter layers tuned to a second color state at a second time, in accordance with some embodiments of the disclosure;

FIG. 12C depicts a diagram of a stacked sensor configuration using one imaging sensor layer and two dynamically tunable color filter layers tuned to a third color state at a third time, in accordance with some embodiments of the disclosure;

FIG. 12D shows a chart detailing a first order in which tunable color filter layers may switch between color states at different times, in accordance with some embodiments of the disclosure;

FIG. 12E shows a chart detailing a second order in which tunable color filter layers may switch between color states at different times, in accordance with some embodiments of the disclosure;

FIG. 13A depicts a diagram of a stacked sensor configuration using one imaging sensor layer and one dynamically tunable color filter layer tuned to a first color state at a first time, in accordance with some embodiments of the disclosure;

FIG. 13B depicts a diagram of a stacked sensor configuration using one imaging sensor layer and one dynamically tunable color filter layer tuned to a second color state at a second time, in accordance with some embodiments of the disclosure;

FIG. 13C depicts a diagram of a stacked sensor configuration using one imaging sensor layer and one dynamically tunable color filter layer tuned to a third color state at a third time, in accordance with some embodiments of the disclosure;

FIG. 13D shows a chart detailing a first order in which a tunable color filter layer may switch between color states at different times, in accordance with some embodiments of the disclosure;

FIG. 13E shows a chart detailing a second order in which a tunable color filter layer may switch between color states at different times, in accordance with some embodiments of the disclosure;

FIG. 13F shows a chart detailing a third order in which a tunable color filter layer may switch between color states at different times, in accordance with some embodiments of the disclosure;

FIG. 14 depicts a system including a server, a communication network, and a computing device for performing the methods and processes noted herein, in accordance with some embodiments of the disclosure;

FIG. 15 is a flowchart of the process for capturing an image with an image sensor operatively connected to control circuitry, in accordance with some embodiments of the disclosure;

FIG. 16 is a flowchart of the process for manufacturing a stacked sensor configuration, in accordance with some embodiments of the disclosure;

FIG. 17 is a flowchart of the process for capturing an image with an image sensor utilizing a tunable color filter, in accordance with some embodiments of the disclosure;

FIG. 18 is a flowchart of the process for manufacturing a stacked sensor configuration with a tunable color filter, in accordance with some embodiments of the disclosure;

FIG. 19 depicts a diagram of a camera device utilizing a tunable color filter, in accordance with some embodiments of the disclosure;

FIG. 20 depicts a diagram of a smartphone with a camera utilizing a tunable color filter, in accordance with some embodiments of the disclosure;

FIG. 21 depicts a diagram of an extended reality device utilizing a tunable color filter, in accordance with some embodiments of the disclosure;

FIG. 22 depicts a diagram of a medical imaging device utilizing a tunable color filter, in accordance with some embodiments of the disclosure.

The drawings are intended to depict only typical aspects of the subject matter disclosed herein, and therefore should not be considered as limiting the scope of the disclosure. Those skilled in the art will understand that the structures, systems, devices, and methods specifically described herein and illustrated in the accompanying drawings are non-limiting embodiments and that the scope of the present invention is defined solely by the claims.

### DETAILED DESCRIPTION

In order to address the drawbacks of the previously mentioned camera systems, there thus arises a need for an image sensor configured such that each pixel or pixel location may capture all color components, whereby the color components are captured and reconstructed in a more efficient manner and without the shortcomings of demosaicing. Accordingly, a camera device utilizing a stacked sensor system is provided.

A stacked sensor system features color filters sandwiched between multiple layers of transparent image sensors. Transparent image sensors leverage the unique properties of atomically thin two-dimensional (2D) materials like graphene, transition metal dichalcogenides (TMDs) like MoS2, and others. These 2D materials, when assembled into photodetector device structures, enable highly transparent yet photoactive sensors. The extreme thinness of the active layers in the stacked sensor, typically just a few atomic layers thick, results in superior transparency for accurate color capturing. For example, graphene is a single atomic layer of carbon, while MoS2 used is often 3-4 atomic layers thick (<1 nm). By sandwiching these ultrathin 2D material layers between transparent electrodes like indium tin oxide (ITO), researchers have demonstrated image sensors with an exceptional optical transparency of 93%. Such a stacked sensor configuration addresses the shortcomings of demosaicing interpolation as the resolution and detail of reconstructed images are sufficiently maintained at each pixel. Furthermore, the compact design of the stacked sensor addresses the problems associated with the multi-sensor design featuring the prisms and beam-splitters, because there are no parallax errors and stitching issues when combining the images from slightly offset sensors. Details on how to select the color filters and how to compute RGB channel values will be described in greater detail below.

Additionally, other embodiments of the stacked sensor reduce the number of layers in the sensor by employing a dynamically tunable color filter that accommodates at least two switchable colors. For example, a binary color filter uses time-multiplexed image capturing techniques to realize full-resolution color capturing in order to avoid the demosaicing and the loss of spatial resolution in color image capturing with Bayer patterns. Moreover, reducing the number of layers in the stacked sensor reduces the ultimate cost in assembling the sensor, as well as minimizing any challenges presented in the precise multi-layer alignment, as further described below.

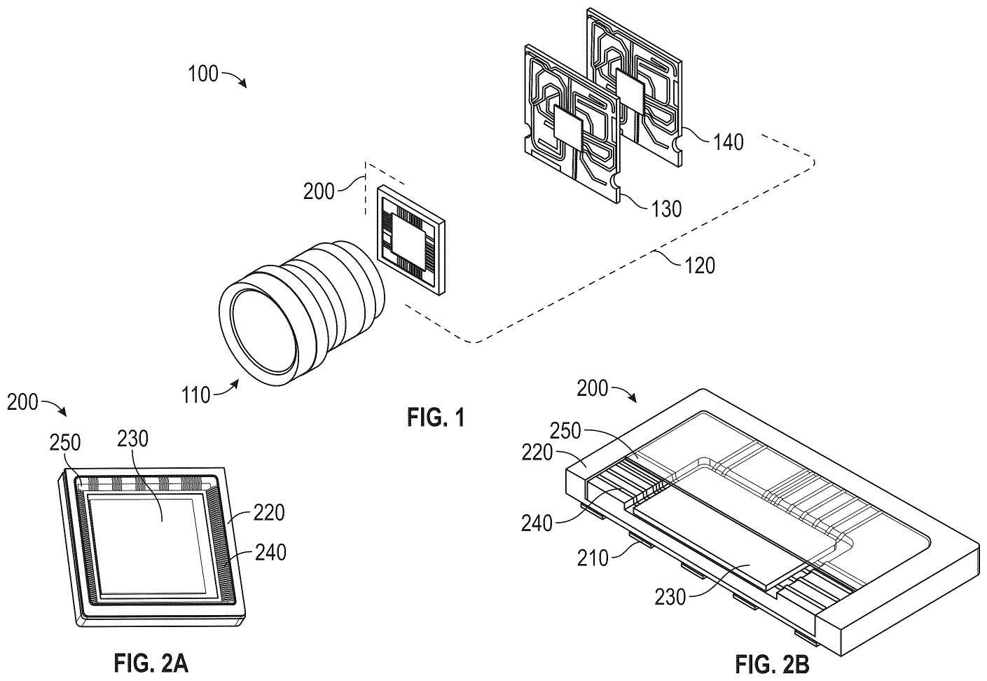

FIGS. 1-2B depict a camera device and its internal hardware components, in accordance with some embodiments of the disclosure.

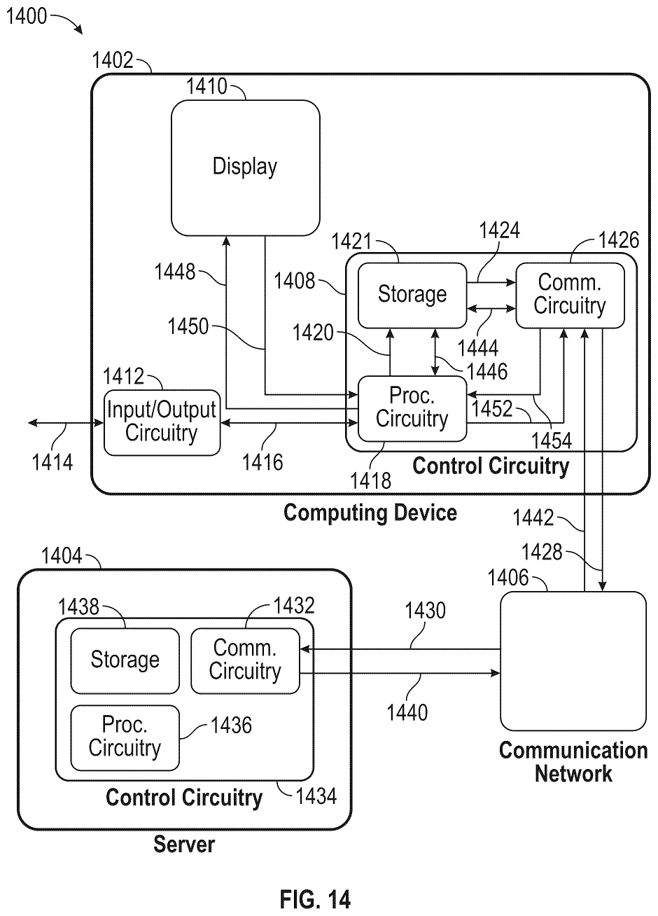

The functions of a camera device are executed using hardware components, such as control circuitry. In some implementations, the camera device is camera device 100 as shown in FIG. 1. In some embodiments, the control circuitry of camera device 100 is control circuitry 1408, as further described in relation to FIG. 14. The control circuitry of camera device 100 communicates with image sensor 200 of FIG. 2A to capture the various dominant wavelengths of incident light (i.e., all wavelengths of light including the visible spectrum). In some approaches, camera device 100 is composed of other hardware components that assist in capturing, reconstructing and displaying images, such as lens 110, an aperture (e.g., a shutter), a flash, a viewfinder, an autofocus system, a camera body, a non-transitory memory and a display, among others.

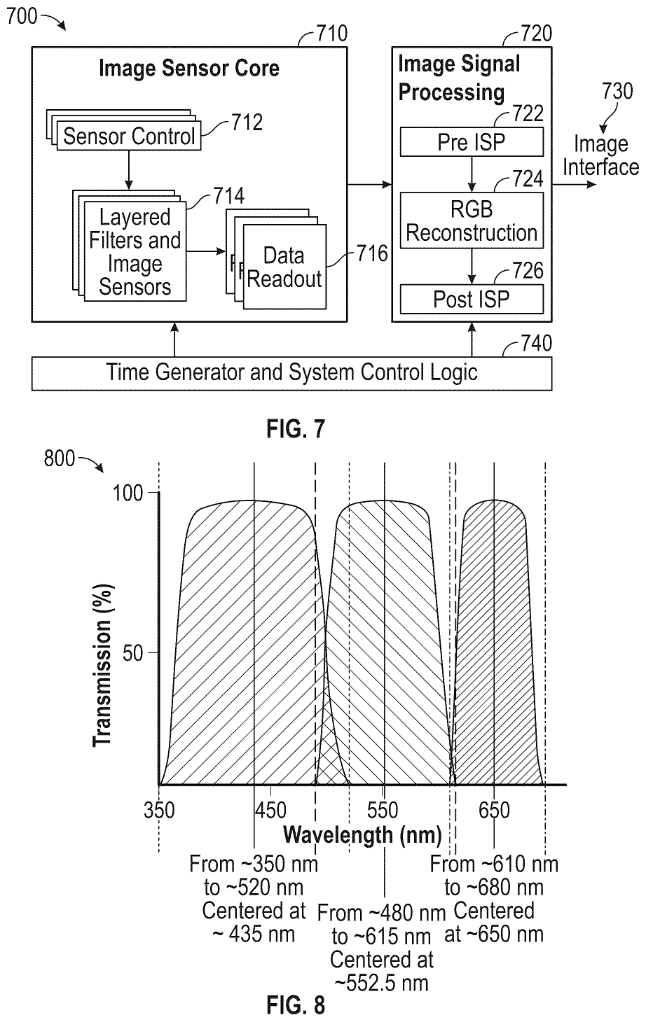

In some implementations, camera device 100 includes image signal processor 130 and interface circuitry 140. In some embodiments, camera device 100 receives incident light that is focused through lens 110 or some other optics. The incident light, funneled through lens 110, strikes image sensor 200, which converts the electrons of the incident light into a voltage and subsequently into a digital value. The digital signal is analyzed by image signal processor 130 and the resulting data may be displayed to a user via interface circuitry 140 and a display screen. Further details regarding image data processing are provided in relation to FIG. 7.

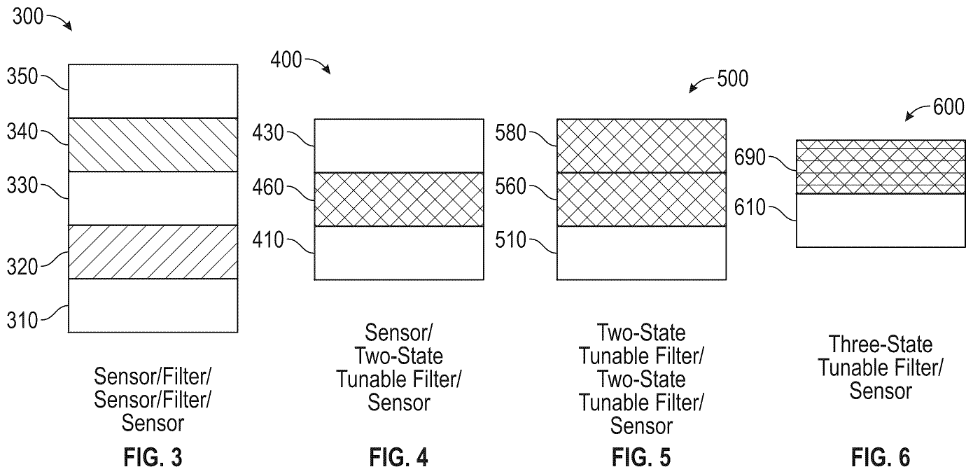

A more detailed view of image sensor 200 is depicted in FIGS. 2A-2B. As shown in FIGS. 2A-2B, image sensor 200 includes contact pads 210, packaging 220, sensor chip 230, wire bonds 240 and cover glass 250. In some embodiments, sensor chip 230 is a solid-state image sensor chip that contains a plurality of pixels made of light-sensitive materials and micro electrical components. The stacked sensor configuration includes a sensor area including a plurality of pixels, as is described in further detail regarding FIGS. 3-6 and 9-13.

FIG. 3 depicts a stacked sensor configuration using three imaging sensor layers and two color filter layers, in accordance with some embodiments of the disclosure.

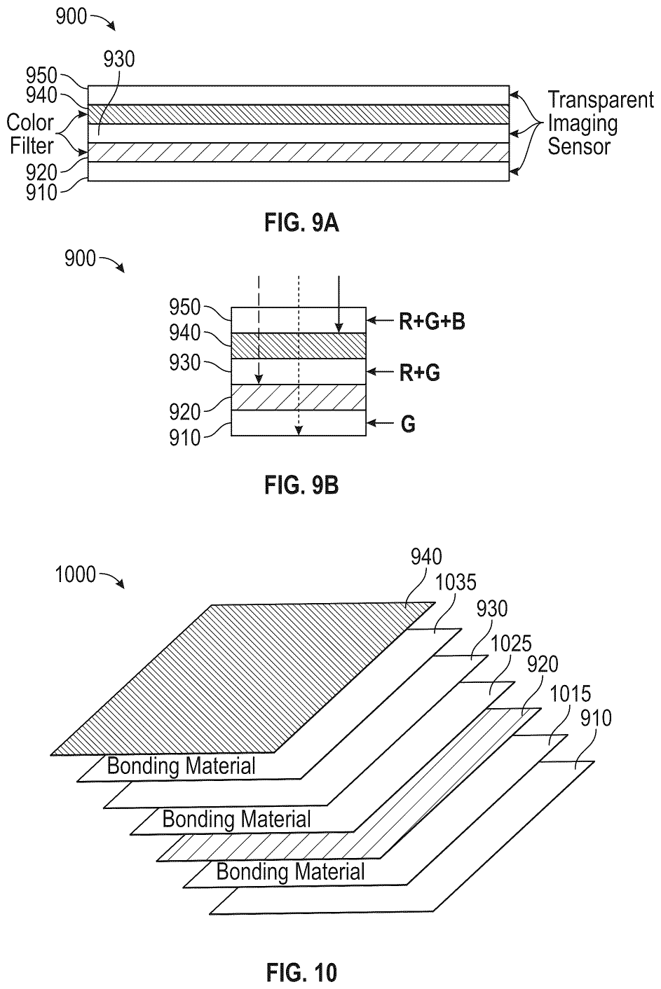

FIG. 3 shows stacked sensor 300, which is intended to be implemented on or at each pixel or pixel location of sensor chip 230 of FIGS. 2A-2B. In some approaches, stacked sensor 300 comprises first imaging sensor layer 310, first color filter 320 disposed over first imaging sensor layer 310, second imaging sensor layer 330 disposed over first color filter 320, second color filter 340 disposed over second imaging sensor layer 330, and third imaging sensor layer 350 disposed over second color filter 340. In some embodiments, each imaging sensor layer is a transparent imaging sensor layer. In some implementations, only the top imaging sensor layer 350 and middle imaging sensor layer 330 are transparent imaging sensor layers, while the bottommost imaging sensor layer 310 isa normal (e.g., non-transparent, traditional, complementary metal oxide semiconductor (CMOS), or the like) imaging sensor layer. In the above example configuration, the bottom imaging sensor layer is a normal imaging sensor layer because it is not necessary for any component of the incident light to pass through it. Further examples of implementing stacked sensor 300 for real-time image capturing are provided in relation to FIGS. 9A-9B.

In the context of this disclosure, the term “over” is used in a broad sense and may encompass several scenarios. These scenarios are not mutually exclusive and the term “over” should not be limited to any single interpretation among them. 1. Indirect Contact: The term “over” may imply a situation where an object is positioned over another object, but they are not in direct contact. There is at least one intervening object between them. This intervening object could be a solid, liquid, gas, or even a vacuum. 2. Selective Contact: The term “over” may also refer to a situation where an object is over and in contact with one object, but not in contact with another object on the other side. In this scenario, there is at least one intervening object between the first object and the object on the other side. 3. Direct Contact: The term “over” may denote a situation where an object is over and in direct contact with objects on either side. This caveat is intended to provide a comprehensive understanding of the term “over” as used in this patent application. The term is used to provide breadth and flexibility in the interpretation of the patent claims, and should not be construed in a limiting sense.

In some approaches, transparent imaging sensors have a sensitivity curve and a transparency curve relative to the wavelength of the incident light captured by camera device 100. The sensitivity curve indicates how effectively the transparent imaging sensor can detect light at specific wavelengths. The transparency curve indicates the amount of incident light that can be transmitted to image sensor 200 at specific wavelengths. The control circuitry measures the properties of the light transmitted to the first imaging sensor layer 310, second imaging sensor layer 330, and third imaging sensor layer 350. Factors such as the materials used in the photodetector sensor and the design of any integrated layers, for example, can influence the transparency curve, affecting the sensor's performance in capturing images across the light spectrum.

In some embodiments, the average transparency p is used to indicate the overall transparency of one or more layers of image sensor 200 (e.g., transparent imaging sensor layers 310, 330, 350, or the like). In another embodiment, three different average transparency values pᵣ, p_{g} and p_{b} are used to indicate the transparency of image sensor 200 with regard to three different color components, red, green, and blue. For example, the average transparencies of image sensor 200 may be pᵣ=91%, p_{g}=94% and p_{b}=93%.

FIG. 4 depicts a stacked sensor configuration using two imaging sensor layers and one dynamically tunable color filter layer, in accordance with some embodiments of the disclosure.

FIG. 4 shows stacked sensor 400, which is intended to be implemented on or at each pixel or pixel location of sensor chip 230 of FIGS. 2A-2B. In some approaches, the configuration of stacked sensor 400 allows for full-resolution color imaging sensors with fewer layers. In some embodiments, stacked sensor 400 comprises two imaging sensor layers and one tunable color filter layer, where the tunable color filter layer is configured to switch between at least two different color states at two or more time periods in order to filter the various components of incident white light. For example, stacked sensor 400 comprises first transparent imaging sensor layer 410, tunable color filter layer 460 disposed over first transparent imaging sensor layer 410 and second transparent imaging sensor layer 430 disposed over color filter layer 460. In some implementations, first transparent imaging sensor layer 410 and second transparent imaging sensor layer 430 are the same imaging sensors as first imaging sensor layer 310 and second imaging sensor layer 330 as further described in relation to FIG. 3. In some embodiments, tunable color filter layer 460 is an electrically tunable color filter with a wide color gamut that is capable of high frequency color state switching. In some implementations, imaging sensor layer 410, at the bottom of the stack, is a normal imaging sensor layer.

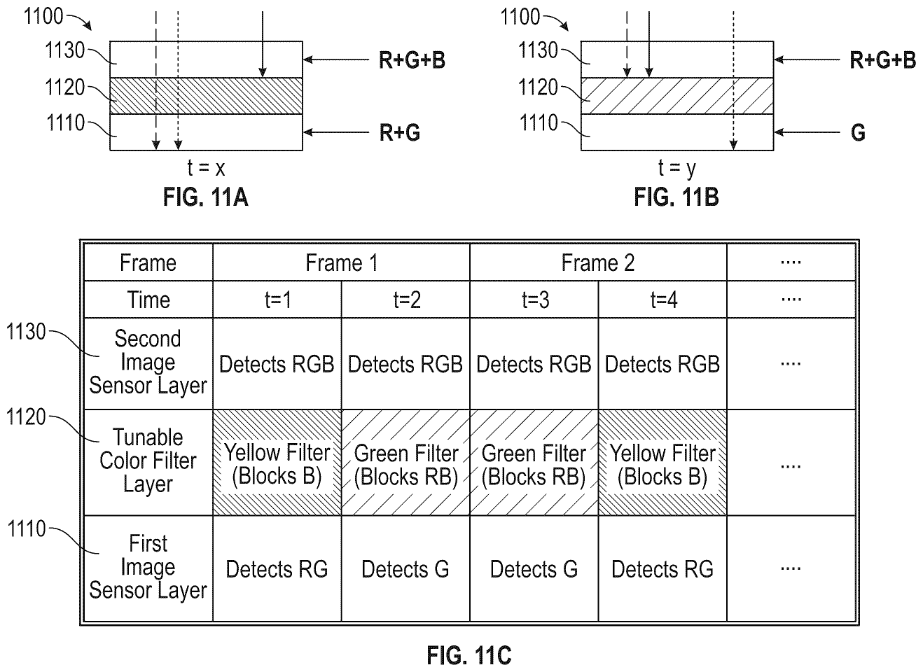

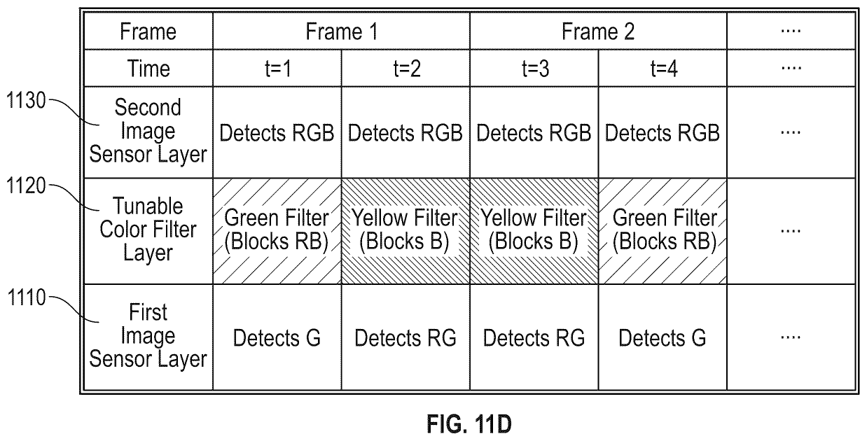

In some approaches, tunable color filter layer 460 changes color states to filter the components of incident white light in a time-multiplexed manner. For example, if tunable color filter layer 460 is configured to switch between only two color states, tunable color filter layer 460 will operate in two different color states over two time periods, with light capturing occurring during both time periods. For example, during a first time period, tunable color filter layer 460 will be tuned to yellow, such that only R (red) and G (green) light components are captured by imaging sensor layer 410. The light after the first capturing will reach an absorptive surface, so that the light is not refracted back to the transparent sensors. During the second time period, tunable color filter layer 460 will be tuned to green, such that R and B (blue) light components are filtered and only the G component is received by imaging sensor layer 410. The first and second capturing processes will then provide the data for the reconstruction of the R, G and B components in full resolution, as described in greater detail below. In some embodiments, switching the color state of tunable color filter layer 460 is electronically or optically controlled. Further examples of implementing stacked sensor 400 for real-time image capturing are provided in relation to FIG. 11.

FIG. 5 depicts a stacked sensor configuration using one imaging sensor layer and two dynamically tunable color filter layers, in accordance with some embodiments of the disclosure.

FIG. 5 shows stacked sensor 500, which is intended to be implemented on or at each pixel or pixel location of sensor chip 230 of FIGS. 2A-2B. In some embodiments, stacked sensor 500 comprises one imaging sensor layer and two tunable color filter layers, where each of the tunable color filter layers is configured to switch between at least two different color states at three or more time periods in order to filter the various components of incident white light. In some approaches, stacked sensor 500 comprises imaging sensor layer 510, first tunable color filter layer 560 disposed over imaging sensor layer 510 and second tunable color filter layer 580 disposed over first tunable color filter layer 560. In the configuration of stacked sensor 500, imaging sensor layer 510 may be a transparent imaging sensor layer or a normal imaging sensor layer. In some implementations, imaging sensor layer 510 is the same imaging sensor as first imaging sensor layer 310 and second imaging sensor layer 330, as further described in relation to FIG. 3, or first transparent imaging sensor layer 410 and second transparent imaging sensor layer 430, as further described in relation to FIG. 4. In some embodiments, first tunable color filter layer 560 and second tunable color filter layer 580 are the same as tunable color filter layer 460, as further described in relation to FIG. 4.

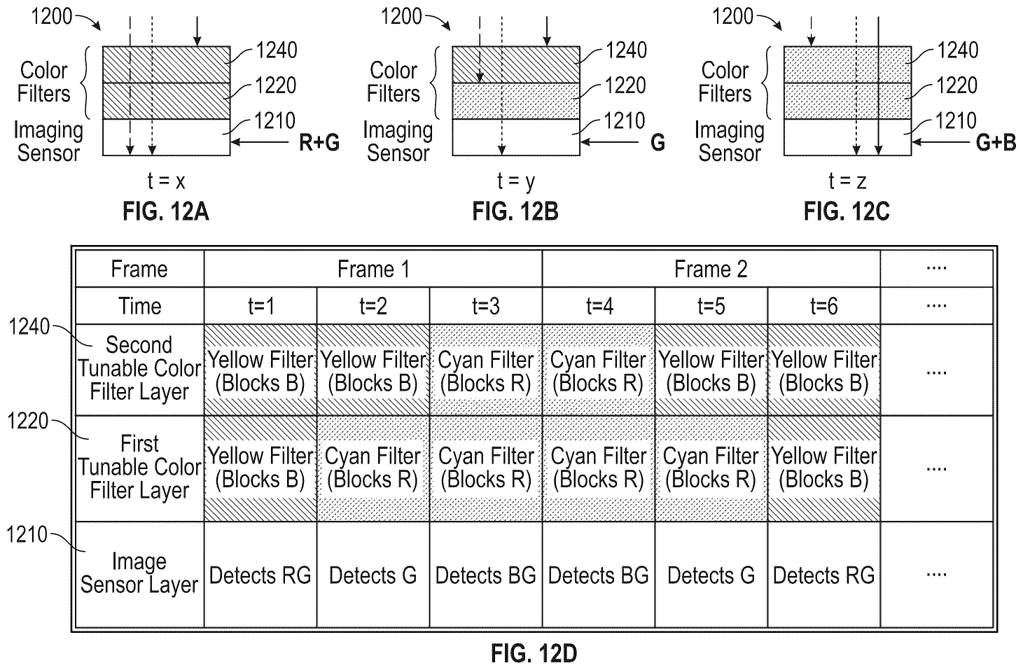

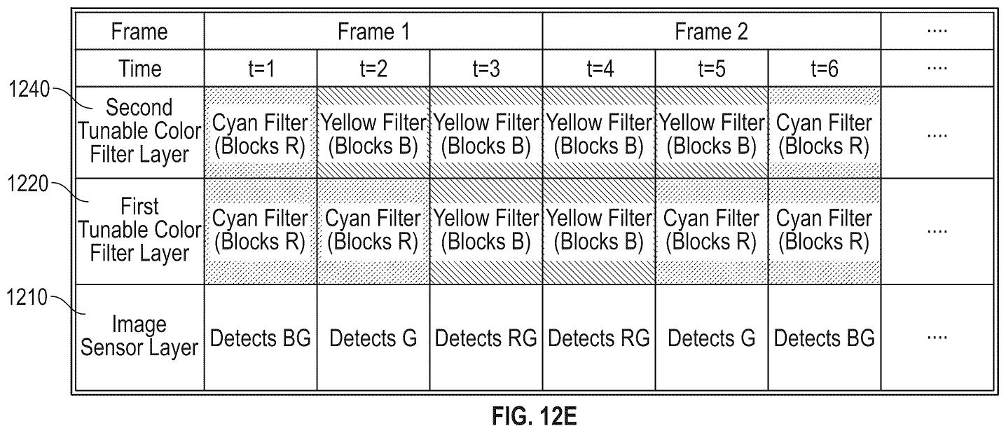

In some approaches, first tunable color filter layer 560 and second tunable color filter layer 580 change color states to filter the components of incident white light in a triple time-multiplexed manner. For example, if each of first tunable color filter layer 560 and second tunable color filter layer 580 is configured to switch between only two color states, first tunable color filter layer 560 and second tunable color filter layer 580 will each operate in two different color states over three time periods, with light capturing occurring during all three time periods. For example, during a first time period, first tunable color filter layer 560 will be tuned to cyan, and second tunable color filter layer 580 will be tuned to yellow. During a second time period, both first tunable color filter layer 560 and second tunable color filter layer 580 will be tuned to yellow. During a third time period, both first tunable color filter layer 560 and second tunable color filter layer 580 will be tuned to cyan. Such an example configuration provides for capturing the R, G and B color components, which will be subsequently reconstructed at each pixel in full resolution. Further examples of implementing stacked sensor 500 for real-time image capturing are provided in relation to FIG. 12.

FIG. 6 depicts a stacked sensor configuration using one imaging sensor layer and one dynamically tunable color filter layer, in accordance with some embodiments of the disclosure.

FIG. 6 shows stacked sensor 600, which is intended to be implemented on or at each pixel or pixel location of sensor chip 230 of FIGS. 2A-2B. In some embodiments, stacked sensor 600 comprises one imaging sensor layer and one tunable color filter layer, where the tunable color filter layer is configured to switch between three different color states at three or more time periods in order to filter the various components of incident white light. In some approaches, stacked sensor 600 comprises imaging sensor layer 610 and tunable color filter layer 690 disposed over imaging sensor layer 610. In the configuration of stacked sensor 600, imaging sensor layer 610 may be a transparent imaging sensor layer or a normal imaging sensor layer, as RGB light components are not required to pass through imaging sensor layer 610 to a different color filter. In some implementations, imaging sensor layer 610 is the same imaging sensor as first imaging sensor layer 310 and second imaging sensor layer 330, as further described in relation to FIG. 3; first transparent imaging sensor layer 410 and second transparent imaging sensor layer 430, as further described in relation to FIG. 4; or imaging sensor layer 510 as further described in relation to FIG. 5.

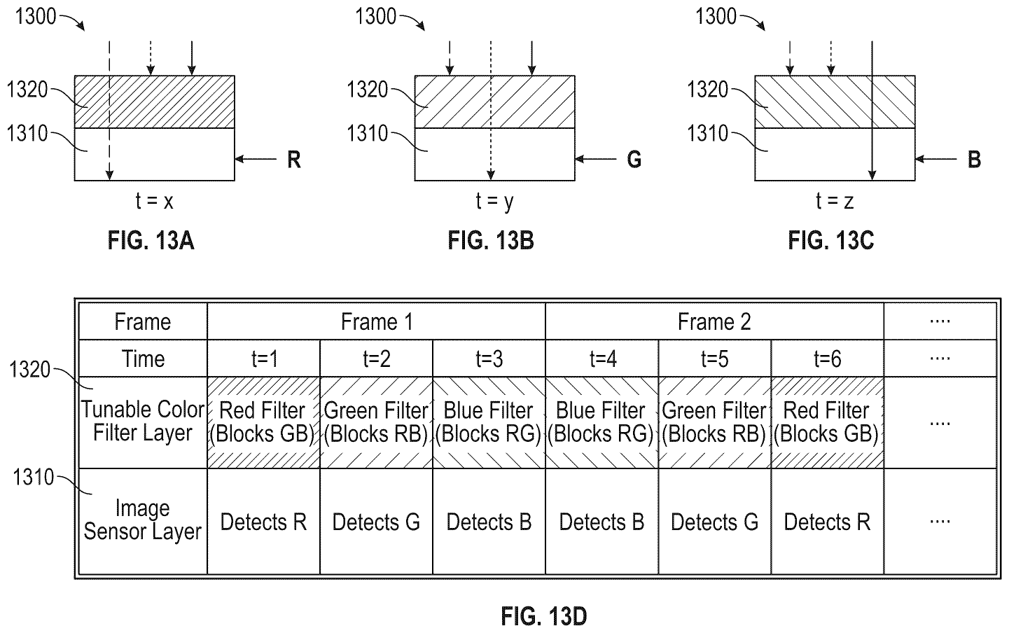

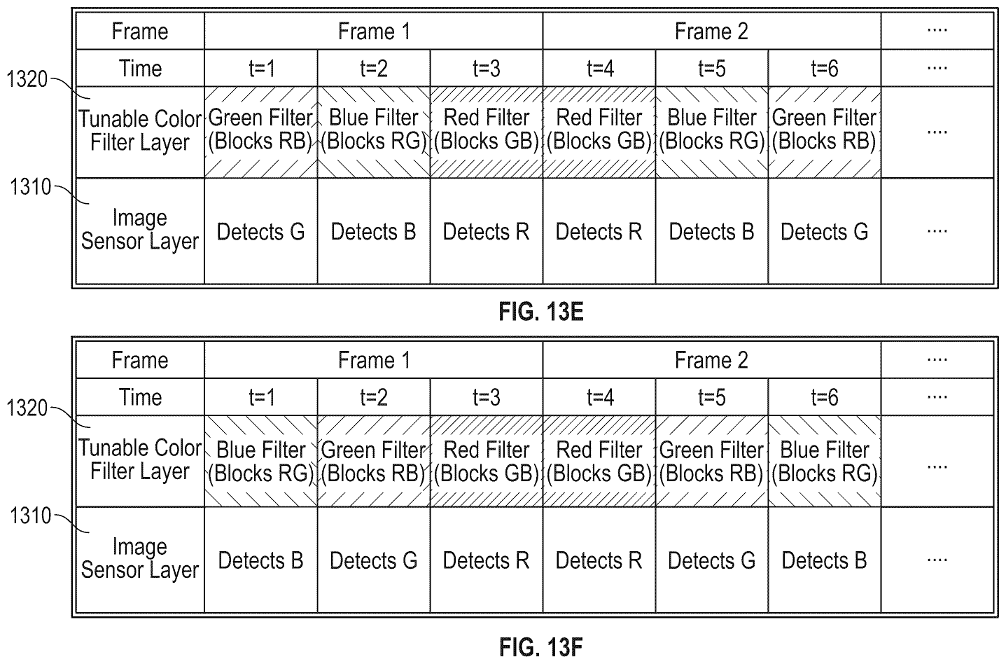

In some approaches, tunable color filter layer 690 changes between three different color states in order to filter the components of incident white light in a triple time-multiplexed manner. For example, tunable color filter layer 690 is configured to switch between an R color state, a G color state and a B color state. Thus, tunable color filter layer 690 will operate in a different color state for each of three separate time periods, with light capturing occurring during all three time periods. As a nonlimiting example, during a first time period, tunable color filter layer 690 will be tuned to red. During a second time period, tunable color filter layer 690 will be tuned to green, and during a third time period, tunable color filter layer 690 will be tuned to blue. Such an example configuration provides for capturing the R, G and B color components, which will be subsequently reconstructed at each pixel in full resolution. Further examples of implementing stacked sensor 600 for real-time image capturing are provided in relation to FIG. 13.

It should be appreciated that any color filter as previously described may be a plasmonic color filter or a dielectric subwavelength grating filter, which may improve the color filter wavelength resolution, extend the color filter's lifetime, and/or reduce the manufacturing cost.

FIG. 7 depicts the components involved in processing image sensor data, in accordance with some embodiments of the disclosure.

Image sensor core 710 is the central component of modern imaging systems and digital camera devices, responsible for the initial capturing of light and converting it into digital signals. In some embodiments, image sensor core 710 interfaces with layered and/or stacked image sensors 714, which detect and measure the light intensity and color in the scene. In some implementations, layered and/or stacked image sensors 714 are charge-coupled device (CCD) or complementary metal-oxide-semiconductor (CMOS) sensors. In some approaches, layered and/or stacked image sensors 714 are any of the stacked sensors as previously described in relation to FIGS. 3-6. Sensor control unit 712 manages the operation of these sensors, ensuring optimal performance by adjusting parameters such as exposure time and gain. In the context of this patent application, the terms “layer,” “stack” and variants thereof are used in a broad sense and may encompass one layer over another with the nonlimiting meaning of “over” as set forth above.

After light is captured, the data undergoes data readout process 716, where the analog signals are converted to digital form and transferred out of layered and/or stacked image sensors 714. In some embodiments, the analog signals are converted into digital data through analog-to-digital converters (ADCs). This digital data represents the raw image, which is then transferred from the sensor array to pre-ISP 722 and subsequently to post-ISP 726, which are included in image signal processing (ISP) procedure 720. Raw data is processed by pre-ISP 722, which performs initial tasks such as noise reduction. The image processing 720 includes the processes performed via pre-image signal processor (pre-ISP) 722, RGB reconstruction 724 and post-image signal processor (post-ISP) 726, which performs tasks such as color correction. In some embodiments, a time generator and system control logic 740 controls the image sensor core and/or the image signal processing 720.

Following the processing performed by pre-ISP 722, RGB reconstruction 724 is carried out in order to reconstruct the image sensor data into full-color resolution. In some embodiments, equations such as those discussed herein with reference to FIGS. 9A and 9B may be provided, e.g., for the layered filters and image sensor 714.

Once RGB reconstruction 724 is complete and full-color resolution is realized, post-ISP 726 is performed to further refine the raw image data. In some embodiments, post-ISP 726 applies more sophisticated processing techniques to enhance the image further. In some approaches, this includes techniques such as color enhancement, contrast adjustment, sharpening, and sometimes even high dynamic range (HDR) processing. The post-ISP ensures that the final image is of high quality and ready for display or storage.

In some embodiments, the processed image data is transferred via image interface 730. Image interface 730 delivers the final image data to the display device, storage media, or any other output medium. Image interface 730 ensures efficient and accurate transmission of the high-quality image, completing the entire image capture and processing workflow.

FIG. 8 depicts a transmittance curve for different color filters, in accordance with some embodiments of the disclosure.

Like transparent imaging sensors, color filters are normally associated with a transparency curve as well. In some approaches, the average transparency t can be used to indicate the transparency of the color filters. For example, the device achieves an average transparency t=about 95% for all colors. In some embodiments, a different average transparency percentage for each different color filter can be used. In some implementations, transparency is a function of incoming wavelength, and transparency is approximated, e.g., by integration or an average.

Furthermore, names of various colors are somewhat subjective. The point where visible light and ultraviolet or infrared light begins can vary slightly by human observer. Where specific colors or wavelengths are discussed, it is to be generally understood that exact wavelengths and corresponding names of colors are imprecise and subjective. As such, as used herein, the term “substantially” is intended to reflect the somewhat imprecise nature of definitions of color. As is appreciated by those of skill in the art, for example, a substantially blue color filter refers to any suitable filter that blocks substantially green and red light, i.e., the upper wavelengths of the visible spectrum. Additionally, the term “substantially” is associated with the amount of light transmitted through each filter. As described above, a color filter layer is not completely transparent, and some minor portion of the received light is not captured by the color filter due to its inherent properties. For example, as shown above, the transparency of color filters associated with a stacked sensor configuration is approximately 95% for all color components of light. One of skill in the art would appreciate, for example, that substantially allowing a certain component of light to pass through a color filter is intended to mean allowing nearly the entire portion of the certain component of light to pass through the color filter.

Light generally includes ultraviolet, visible, and infrared light. Of these, ultraviolet may include UV-C light having a wavelength between about 200 nm and about 280 nm; UV-B light having a wavelength between about 280 nm and about 315 nm; and UV-A light having a wavelength between about 315 nm and about 400 nm. Some humans perceive ultraviolet light at the higher wavelengths. As such, 400 nm as an upper bound for UV light is one possible limit.

Visible light may include purple light having a wavelength between about 400 nm and about 435 nm; blue light having a wavelength between about 435 nm and about 480 nm; patina light having a wavelength between about 480 nm and about 490 nm; blue green light having a wavelength between about 490 nm and about 500 nm; green light having a wavelength between about 500 nm and about 560 nm; yellow green having a wavelength between about 560 nm and about 580 nm; yellow light having a wavelength between about 580 nm and about 595 nm; orange light having a wavelength between about 595 nm and about 610 nm; red light having a wavelength between about 610 nm and about 750 nm; and purple light having a wavelength between about 750 nm and about 800 nm. Again, these labels for visible color are selected for convenience and do not need to be exact. For example, a substantially red color filter may filter light having wavelengths of between about 600 nm and about 700 nm in some embodiments. In other embodiments, for example, a substantially red color filter may filter relatively narrower or broader ranges of wavelengths of light depending on the application and equipment.

Infrared light may include IR-A light having a wavelength between about 800 nm and about 1400 nm; IR-B light having a wavelength between about 1400 nm and about 3000 nm; and IR-C light having a wavelength between about 3000 nm and about 10000 nm. Some humans perceive infrared light at the lower wavelengths. As such, 800 nm as a lower bound is one possible limit.

Additionally, there can be different ways to design the architecture of the color filter and image sensor layers. In some embodiments, the three layers of image sensors capture three different components of light and those three different components are used to derive the RGB components used in conventional RGB color imaging, as further shown in FIGS. 3 and 9A-9B. For example, a yellow filter may be selected as the first color filter layer based on the consideration that, for some observers, a blue color has the lowest luminance and is to be measured by the first layer of the image sensor before its magnitude is reduced due to a relatively low transmittance rate of the image sensor (that said, it is generally understood that light sensitivity of the human eye may be higher for some individuals when perceiving certain areas of the spectrum making it seem, to some individuals, that certain colors have higher luminance that others). Similarly, a red component may have lower luminance compared to a green component, so the second layer of the image sensor is targeted to measure the red component, while the last layer of the image sensor can be used to measure the green component, which has gone through all the first four layers of transparent materials.

In some implementations, there can be an additional color filter layer on top of the first image sensor layer, and the color transmission property of each layer can also be designed differently. The first color filter layer can filter out the infrared color or other overlapping colors between the R, G, B components, or it can be narrow band passing through filters that only allows certain narrower bands of R, G, B colors to pass through, while the second and third color filter layers will have a matched design. In some embodiments, those color filters layers can be arranged in different color configurations as long as the R, G, B color components of each pixel can be reconstructed.

FIGS. 9A-9B depict a diagram of the stacked sensor configuration using three imaging sensor layers and two color filter layers, in accordance with some embodiments of the disclosure.

In some embodiments, stacked sensor 900 comprises two layers of color filters, sandwiched between three layers of image sensors. For example, stacked sensor 900 includes first imaging sensor layer 910, first color filter layer 920 disposed over first imaging sensor layer 910, second imaging sensor layer 930 disposed over first color filter layer 920, second color filter layer 940 disposed over second imaging sensor layer 930, and third image sensor layer 950 disposed over second color filter layer 940. In some approaches, stacked sensor 900 is the same sensor as stacked sensor 300 of FIG. 3, and first imaging sensor layer 910, first color filter layer 920, second imaging sensor layer 930, second color filter layer 940 and third image sensor layer 950 are the same as first imaging sensor layer 310, first color filter layer 320, second imaging sensor layer 330, second color filter layer 340 and third image sensor layer 350 of FIG. 3, respectively.

Using the example embodiment of FIGS. 9A-9B, the top layer of the sensor is exposed to the entire light spectrum equally without filtering. The light passing through the top layer (e.g., third image sensor layer 950) will be filtered by the yellow color filter (e.g., second color filter 940), where only green and red colors will pass through. In this case, the third layer of the image sensor (e.g., second imaging sensor layer 930) will be able to measure the combined magnitude of the red and green colors. The light passing through the third layer of the image sensor will be filtered by the second layer of color filter (e.g., first color filter 920), where the red color will be filtered, and only green color will be captured by the bottom layer of the image sensor (e.g., first imaging sensor layer 910). The conventional R, G, and B components of each pixel can be subsequently reconstructed from the three captured values, considering the transmittance rate of each sensor and filter layer. Although stacked sensor 900 of this embodiment is described having green and yellow color filters 920 and 940, in other embodiments, other colors for the filters 920 and 940 are provided in any suitable combination.

It may be assumed that the captured value in each pixel of the sensor is represented by L(x, y), which is a combination of the RGB component in a format of L(x, y)=cᵣR+c_{g}G+c_{b}B, where the parameters cᵣ, c_{g}, cₚ are determined by experiments. In some embodiments, there are three measurements for each pixel of the sensor, e.g., for stacked sensor 300 (above) or stacked sensor 900 of FIG. 9, Lᵢ(x, y), i=1, 2, 3. Using the three different average transparency values pᵣ, p_{g} and p_{b}, as previously discussed in relation to FIG. 3, the transmittance rate tⱼᵣ, t_{jg}, t_{jb} of the image sensor may be determined with regard to each color component, where j=1, 2 as the transmittance rate for each R, G, B color of the corresponding color filter layer. In some approaches, the measurements to determine the captured value of each pixel are represented in the formulas (1), (2), and (3).

$${L}_{1} ( x , y ) = {c}_{r} R ( x , y ) + {c}_{g} G ( x , y ) + {c}_{b} B ( x , y ) \qquad ( 1 )$$

$${L}_{2} ( x , y ) = {c}_{r} {p}_{r} {t}_{1 r} R ( x , y ) + {c}_{g} {p}_{g} {t}_{1 g} G ( x , y ) + {c}_{b} {p}_{b} {t}_{1 b} B ( x , y ) \qquad ( 2 )$$

$${L}_{3} ( x , y ) = {c}_{r} {p}_{r} {p}_{r} {t}_{1 r} {t}_{2 r} R ( x , y ) + {c}_{g} {p}_{g} {p}_{g} {t}_{1 g} {t}_{2 g} G ( x , y ) + {c}_{b} {p}_{b} {p}_{b} {t}_{1 b} {t}_{2 b} B ( x , y ) \qquad ( 3 )$$

Considering that all these parameters are known, we can reconstruct the R(x,y), G(x,y), and B(x,y) by solving the linear equations.

Please note, the formulas (1), (2), and (3) are similar for sensors 1100, 1200, and 1300 as appropriate for one or more tunable color filters with the time-dependance aspect visually summarized, for example, in the tables of FIGS. 11C, 11D, 12D, 12E, 13D, 13E, and 13F.

FIG. 10 depicts a stacked sensor including the bonding material in between each layer of the stacked sensor, in accordance with some embodiments of the disclosure.

Manufacturing the stacked sensor requires precise alignment of the various layers comprising the stacked sensor. For example, stacked sensor 1000 is formed by combining first imaging sensor layer 910, first color filter layer 920, second imaging sensor layer 930 and second color filter layer 940 into a stacked configuration, whereby each layer is secured to adjacent layers by bonding material 1015, 1025 and 1035, respectively.

In some embodiments, aligning the layers of transparent image sensors pixel to pixel requires precision engineering techniques, such as lithography for exact placement and the use of alignment marks on the sensors and substrate. This ensures that each layer's pixels will perfectly overlay the pixels of adjacent layers, allowing for accurate color capture without misalignment that could degrade image quality. In some approaches, advanced manufacturing processes and equipment, including high-resolution optical systems, are used to achieve this level of precision in sensor assembly. In some embodiments, accurate alignment of different layers is achieved using methods and systems from the field of semiconductor manufacturing. For example, each of the conventional image sensors is aligned with the Bayer patterns in pixel-to-pixel accuracy.

In some implementations, the precision alignment process introduces misalignments between the different layers of the sensors, color filters and bonding materials between each layer. In-factory calibration is performed to correct any misalignment before a stacked sensor is installed in a device. For example, on a 24×36 mm 54MP sensor, a pixel is about 4 microns (4×10\hat{ }−3 mm) wide. A misalignment of more than 4 microns would result in an improper read of a pixel color component at each of the layers in the sensor. For example, if a misalignment of 4 microns exists between the first layer of the sensor and the second and third layers of the sensor in the Y direction in FIG. 10, then a pixel at position x,y would have its R, G and B components mixed with another pixel at position x, y=1.

In some embodiments, the calibration process results in δx, δy, for the second layer and third layer of the image sensor with regard to the alignment with the first layer of the image sensor. The sensors will still obtain three full resolution color channels, and the final full-resolution color image can be reconstructed given the (δₓ₂, δ_{y2}) and (δₓ₃, δ_{y3}).

In some approaches, a specific calibration pattern is sent to the stacked sensor, and deviations in alignment are compensated. In some implementations, such a calibration process occurs on-device (at power on for example) although the test pattern generation and its propagation toward the sensor stack may require electronics and optics used for that purpose and may not be cost-optimized compared to factory calibration.

In some implementations, the calibration process addresses transparency uniformity issues due to a bonding substrate that is not uniformly transparent and adjusts the transmittance rates pᵣ, p_{g}, p_{b}, and tⱼᵣ, t_{jg}, t_{jb} as functions of pixel coordinates x,y. The equations above to derive R, G, B coordinates for each pixel remain linear, as they are solved for each x,y pair independently. In some embodiments, measuring and adjusting for non-uniformity requires a different test pattern than that used for alignment. For example, an alignment pattern includes a checker-type pattern, whereas a uniformity pattern includes a set of uniform color images.

While the current figure describes each layer of the stacked sensor as being held together via bonding material, it should be appreciated that certain embodiments of the stacked sensor attach image sensors and color filters directly to each other, without the use of a bonding material. For example, surfaces of respective layers are made of different materials and treated such that each layer binds to the next.

FIGS. 11A-11D depict a diagram of a stacked sensor configuration using two imaging sensor layers and one dynamically tunable color filter layer, in accordance with some embodiments of the disclosure.

In some embodiments, stacked sensor 1100 comprises two image sensor layers and one tunable color filter layer, where the tunable color filter layer is configured to switch between at least two different color states at two or more time periods in order to filter the various components of incident white light. For example, stacked sensor 1100 comprises first transparent imaging sensor layer 1110, tunable color filter layer 1120 disposed over first transparent imaging sensor layer 1110 and second transparent imaging sensor layer 1130 disposed over color filter layer 1120. In some approaches, stacked sensor 1100 is the same as stacked sensor 400 of FIG. 4 and first transparent imaging sensor layer 1110, tunable color filter layer 1120 and second transparent imaging sensor layer 1130 are the same as first transparent imaging sensor layer 410, tunable color filter layer 460 and second transparent imaging sensor layer 430 of FIG. 4, respectively.

Using the example embodiments of FIGS. 11A-11D, the capturing performed by the sensors is executed in a time multiplexed manner. For example, second transparent imaging sensor layer 1130 captures (R+G+B), and first transparent imaging sensor layer 1110 captures (R+G). During this first capturing, for example, tunable color filter layer 1120 is tuned to yellow, i.e., filtering out a blue component so that the remaining is a magenta component (i.e., R+G). The light after the first capturing will reach an absorptive surface and there is no refraction back to the transparent sensors. In the second capturing shown in FIGS. 11A-11D, first transparent imaging sensor layer 1110 captures G with tunable color filter layer 1120 tuned to filter out the red and blue light components. In some approaches, the first and second capturing processes provide the data for the reconstruction of R, G and B components in full resolution.

In some embodiments, in the time multiplexed manner, the two captures both have (R+G+B) components that can be used for better sensitivity in luminance capturing by increasing the frequency of switching of the color filters.

While the present example embodiments of FIGS. 11A-11C depict a stacked sensor 1100 beginning the capturing process while tunable color filter layer 1120 is tuned to yellow and during the second capturing changing to green, it should be appreciated that embodiments of a stacked sensor 1100 may begin the capturing process while tunable color filter layer 1120 is tuned to a green filter and during the second capturing, changing to a yellow filter, as shown in FIG. 11D.

In the embodiments shown in FIGS. 11C and 11D, the timings (e.g., yellow at t=1 for frame 1, green at t=2 for frame 1, then green at t=3 for frame 2, and yellow at t=4 for frame 2) ensure that the tunable color filter layer 1120 is switched a minimum number of times between frames, i.e., the tunable color filter layer 1120 stays the same color from frame 1 to frame 2, which confers an advantage of minimizing fatigue on the tunable color filter layer 1120 and other components affected by the switching.

Although the tunable color filter layer 1120 of the stacked sensor 1100 of this embodiment is described as being tuned between yellow and green and in certain time orders, in other embodiments, the tunable color filter layer 1120 is tuned in any suitable combination of colors and in any suitable time order.

FIGS. 12A-12E depict a diagram of a stacked sensor configuration using one imaging sensor layer and two dynamically tunable color filter layers, in accordance with some embodiments of the disclosure.

In some embodiments, stacked sensor 1200 comprises one imaging sensor layer and two tunable color filter layers, where each of the tunable color filter layers is configured to switch between at least two different color states at three or more time periods in order to filter the various components of incident white light. For example, stacked sensor 1200 comprises imaging sensor layer 1210, first tunable color filter layer 1220 disposed over imaging sensor layer 1210 and second tunable color filter layer 1240 disposed over first tunable color filter layer 1220. In some approaches, stacked sensor 1200 is the same as stacked sensor 500 of FIG. 5, and imaging sensor layer 1210, first tunable color filter layer 1220 and second tunable color filter layer 1240 are the same as imaging sensor layer 510, first tunable color filter layer 560 and second tunable color filter layer 580 of FIG. 5, respectively.

Using the example embodiments of FIGS. 12A-12E, the capturing performed by the sensors is executed in a time multiplexed manner similar to the capturing further described in relation to FIGS. 11A-11D. For example, during the first capturing at the first time, first tunable color filter layer 1220 and second tunable color filter layer 1240 are both tuned to yellow, such that the blue light component is blocked and a magenta component (i.e., R+G) is detected at imaging sensor layer 1210. In the second capturing at the second time, first tunable color filter layer 1220 is tuned to cyan, such that the red light component is blocked and second tunable color filter layer 1240 remains tuned to yellow, such that the blue light component is blocked. Using this combination of a cyan and a yellow tuned filter allows only a green component of light to be detected at imaging sensor layer 1210. In the third capturing at the third time, first tunable color filter layer 1220 and second tunable color filter layer 1240 are both tuned to cyan, such that the red light component is blocked and the (G+B) light component passes through the color filters to be detected at imaging sensor layer 1210. In some approaches, the first, second and third capturing processes (i.e., at the first, second and third time periods, respectively) provide the data for the reconstruction of R, G and B components in full resolution.

While the present example embodiments of FIGS. 12A-12D depict stacked sensor 1200 beginning the capturing process while first tunable color filter layer 1220 and second tunable color filter layer 1240 are both tuned to yellow and during the third capturing at the third time changing to cyan, it should be appreciated that other embodiments of stacked sensor 1200 may begin the capturing process (i.e., during the capturing at the first time) while first tunable color filter layer 1220 and second tunable color filter layer 1240 are both tuned to cyan and during the third capturing at the third time, changing to yellow, as shown in FIG. 12E. In other implementations, during the second capturing at the second time, first tunable color filter layer 1220 is tuned to yellow, while second tunable color filter layer 1240 is tuned to cyan and the same image data will result.

As with the embodiments of FIGS. 11C and 11D, the timings of the embodiments of FIGS. 12D and 12E ensure that the tunable color filter layers 1220 and 1240 are switched a minimum number of times within and between frames, which confers an advantage similar to that earlier discussed.

Although the tunable color filter layers 1220 and 1240 of the stacked sensor 1200 of this embodiment are described as being tuned between yellow and cyan and in certain time orders, in other embodiments, the tunable color filter layers 1220 and 1240 are tuned in any suitable combination of colors and in any suitable time order.

FIGS. 13A-13F depict a diagram of a stacked sensor configuration using one imaging sensor layer and one dynamically tunable color filter layer, in accordance with some embodiments of the disclosure.

In some embodiments, stacked sensor 1300 comprises one imaging sensor layer and one tunable color filter layer, where the tunable color filter layer is configured to switch between three different color states at three or more time periods in order to filter the various components of incident white light. For example, stacked sensor 1300 comprises imaging sensor layer 1310 and tunable color filter layer 1320 disposed over imaging sensor layer 1310. In some approaches, stacked sensor 1300 is the same as stacked sensor 600 of FIG. 6 and imaging sensor layer 1310 and tunable color filter layer 1320 are the same as imaging sensor layer 610 and tunable color filter layer 690 of FIG. 6, respectively.

Using the example embodiments of FIGS. 13A-13F, the capturing performed by the sensors is executed in a time multiplexed manner similar to the capturing further described in relation to FIGS. 11A-11D and FIGS. 12A-12E. For example, during the first capturing at the first time, tunable color filter layer 1320 is tuned to red, such that the (G+B) light component is blocked and the red light component passes through the filter to be detected at imaging sensor layer 1310. In the second capturing at the second time, tunable color filter layer 1320 is tuned to green, such that the (R+B) light component is blocked and the green light component passes through the filter to be detected at imaging sensor layer 1310. In the third capturing at the third time, tunable color filter layer 1320 is tuned to blue, such that the (R+G) light component is blocked and the blue light component passes through the filter to be detected at imaging sensor layer 1310. In some approaches, the first, second and third capturing processes (i.e., at the first, second and third time periods, respectively) provide the data for the reconstruction of R, G and B components in full resolution.

While the present example embodiments of FIGS. 13A-13C depict stacked sensor 1300 beginning the capturing process while tunable color filter layer 1320 is tuned red, changing to green for the second capturing and changing to blue for the third capturing, it should be appreciated that other embodiments of stacked sensor 1300 may begin the capturing process (i.e., during the capturing at the first time) while tunable color filter layer 1320 is tuned to green, changing to blue for the second capturing and changing to red for the third capturing, as shown in FIG. 13E. In other implementations, stacked sensor 1300 begins the capturing process while tunable color filter layer 1320 is tuned blue, changing to green for the second capturing and changing to red for the third capturing, as shown in FIG. 13F. In general, stacked sensor 1300 may begin the capturing process at the first time while tunable color filter layer 1320 is tuned to any R, G or B color. As long as tunable color filter layer 1320 tunes to the remaining R, G or B colors (i.e., not used during the first capturing at the first time) during the second and third time periods, where tunable color filter layer 1320 tunes to a differently colored filter for each of the second and third time periods, the same image data will result.

As with the embodiments of FIGS. 11C and 11D and 12 and 12E, the timings of the embodiments of FIGS. 13D-13F ensure that the tunable color filter layer 1320 is switched a minimum number of times within and between frames, which confers an advantage similar to that earlier discussed.

Although the tunable color filter layer 1320 of the stacked sensor 1300 of this embodiment is described as being tuned among red, green and blue and in certain time orders, in other embodiments, the tunable color filter layer 1320 is tuned in any suitable combination of colors and in any suitable time order.

### Communication System

FIG. 14 depicts a system including a server, a communication network, and a computing device for performing the methods and processes noted herein, in accordance with some embodiments of the disclosure.

A communication system is provided including a computing device, a server, and a communication network. Both the server and the communication network can exist in multiple forms and can connect directly or indirectly. The computing device includes control circuitry, a display, and I/O circuitry. The control circuitry can execute systems, methods, processes, and outputs. Both the computing device and server include control circuitry and storage, which can store content, metadata, data, user profiles, messages, and commands for an application. The computing device communicates with an I/O device and can receive and process user inputs locally or transmit them to the remote server for processing. Both the server and the computing device can transmit and receive content via the communication network or directly, and the processing circuitry receives the user input and converts it to digital signals.

In some embodiments, the system is a distributed network architecture with an edge device (a type of computing device 1402), a cloud server (a type of server 1404), and an internet of things (IoT) network (a type of communication network 1406). Both the edge device and server have microservices and data lakes. The edge device includes a user interface and I/O ports. User interactions can be processed at the edge or in the cloud. The system can transmit and receive digital assets via the IoT network. The edge device communicates with an IoT device and can be various types of smart devices capable of displaying and interacting with digital content. The communication paths in the system can be optimized for latency and bandwidth efficiency.

FIG. 14 depicts a block diagram of system 1400, in accordance with some embodiments. The system is shown to include computing device 1402, server 1404, and a communication network 1406. It is understood that while a single instance of a component may be shown and described relative to FIG. 14, additional embodiments of the component may be employed. For example, server 1404 may include, or may be incorporated in, more than one server. Similarly, communication network 1406 may include, or may be incorporated in, more than one communication network. Server 1404 is shown communicatively coupled to computing device 1402 through communication network 1406. While not shown in FIG. 14, server 1404 may be directly communicatively coupled to computing device 1402, for example, in a system absent or bypassing communication network 1406.

Communication network 1406 may include one or more network systems, such as, without limitation, the Internet, LAN, Wi-Fi, wireless, or other network systems suitable for audio processing applications. The system 1400 of FIG. 14 excludes server 1404, and functionality that would otherwise be implemented by server 1404 is instead implemented by other components of the system depicted by FIG. 14, such as one or more components of communication network 1406. In still other embodiments, server 1404 works in conjunction with one or more components of communication network 1406 to implement certain functionality described herein in a distributed or cooperative manner. Similarly, the system depicted by FIG. 14 excludes computing device 1402, and functionality that would otherwise be implemented by computing device 1402 is instead implemented by other components of the system depicted by FIG. 14, such as one or more components of communication network 1406 or server 1404 or a combination of the same. In other embodiments, computing device 1402 works in conjunction with one or more components of communication network 1406 or server 1404 to implement certain functionality described herein in a distributed or cooperative manner.

Computing device 1402 includes control circuitry 1408, display 1410 and input/output (I/O) circuitry 1412. Control circuitry 1408 may be based on any suitable processing circuitry and includes control circuits and memory circuits, which may be disposed on a single integrated circuit or may be discrete components. As referred to herein, processing circuitry should be understood to mean circuitry based on at least one microprocessors, microcontrollers, digital signal processors, programmable logic devices, field-programmable gate arrays (FPGAs), application-specific integrated circuits (ASICs), system-on-chip (SoC), application-specific standard parts (ASSPs), indium phosphide (InP)-based monolithic integration and silicon photonics, non-classical devices, organic semiconductors, compound semiconductors, “More Moore” devices, “More than Moore” devices, cloud-computing devices, combinations of the same, or the like, and may include a multi-core processor (e.g., dual-core, quad-core, hexa-core, or any suitable number of cores). In some embodiments, processing circuitry may be distributed across multiple separate processors or processing units, for example, multiple of the same type of processing units (e.g., two Intel Core i9 processors) or multiple different processors (e.g., an Intel Core i7 processor and an Intel Core i9 processor). Some control circuits may be implemented in hardware, firmware, or software. Control circuitry 1408 in turn includes communication circuitry 1426, storage 1421 and processing circuitry 1418. Either of control circuitry 1408 and 1434 may be utilized to execute or perform any or all the systems, methods, processes, and outputs of one or more of FIGS. 1-7, 9-13, and 15-22, or any combination of steps thereof (e.g., as enabled by processing circuitries 1418 and 1436, respectively).

In addition to control circuitry 1408 and 1434, computing device 1402 and server 1404 may each include storage (storage 1421, and storage 1438, respectively). Each of storages 1421 and 1438 may be an electronic storage device. As referred to herein, the phrase “electronic storage device” or “storage device” should be understood to mean any device for storing electronic data, computer software, or firmware, such as random-access memory, read-only memory, cloud-based storage, hard drives, optical drives, digital video disc (DVD) recorders, compact disc (CD) recorders, BLU-RAY disc (BD) recorders, BLU-RAY 3D disc recorders, digital video recorders (DVRs, sometimes called personal video recorders, or PVRs), solid state devices, quantum storage devices, gaming consoles, gaming media, or any other suitable fixed or removable storage devices, and/or any combination of the same. Each of storage 1421 and 1438 may be used to store several types of content, metadata, and/or other types of data. Non-volatile memory may also be used (e.g., to launch a boot-up routine and other instructions). Cloud-based storage may be used to supplement storages 1421 and 1438 or instead of storages 1421 and 1438. In some embodiments, a user profile and messages corresponding to a chain of communication may be stored in one or more of storages 1421 and 1438. Each of storages 1421 and 1438 may be utilized to store commands, for example, such that when each of processing circuitries 1418 and 1436, respectively, are prompted through control circuitries 1408 and 1434, respectively. Either of processing circuitries 1418 or 1436 may execute any of the systems, methods, processes, and outputs of one or more of FIGS. 1-7, 9-13, and 15-22, or any combination of steps thereof.

In some embodiments, control circuitry 1408 and/or 1434 executes instructions for an application stored in memory (e.g., storage 1421 and/or storage 1438). Specifically, control circuitry 1408 and/or 1434 may be instructed by the application to perform the functions discussed herein. In some embodiments, any action performed by control circuitry 1408 and/or 1434 may be based on instructions received from the application. For example, the application may be implemented as software or a set of and/or one or more executable instructions that may be stored in storage 1421 and/or 1438 and executed by control circuitry 1408 and/or 1434. The application may be a client/server application where only a client application resides on computing device 1402, and a server application resides on server 1404.

The application may be implemented using any suitable architecture. For example, it may be a stand-alone application wholly implemented on computing device 1402. In such an approach, instructions for the application are stored locally (e.g., in storage 1421), and data for use by the application is downloaded on a periodic basis (e.g., from an out-of-band feed, from an Internet resource, or using another suitable approach). Control circuitry 1408 may retrieve instructions for the application from storage 1421 and process the instructions to perform the functionality described herein. Based on the processed instructions, control circuitry 1408 may determine a type of action to perform based at least in part on input received from I/O circuitry 1412 or from communication network 1406.

The computing device 1402 is configured to communicate with an I/O device (not shown) via the I/O circuitry 1412. In some embodiments, the user input 1414 is received from the I/O device. A wired and/or wireless connection between the I/O circuitry 1412 and the I/O device is provided in some embodiments. The I/O device may be, for example, at least one of a keyboard, a mouse, a touchscreen, a microphone, a scanner, a joystick, a graphics tablet, a monitor, a printer, speakers, headphones, a projector, a headset, a wearable device, a gaming controller, an external hard drive, a USB hard drive, an SD card, a network interface card (NIC), combinations of the same, or the like.

In client/server-based embodiments, control circuitry 1408 may include communication circuitry suitable for communicating with an application server (e.g., server 1404) or other networks or servers. The instructions for conducting the functionality described herein may be stored on the application server. Communication circuitry may include a cable modem, an Ethernet card, or a wireless modem for communication with other equipment, or any other suitable communication circuitry. Such communication may involve the Internet or any other suitable communication networks or paths (e.g., communication network 1406). In another example of a client/server-based application, control circuitry 1408 runs a web browser that interprets web pages provided by a remote server (e.g., server 1404). For example, the remote server may store the instructions for the application in a storage device.

The remote server may process the stored instructions using circuitry (e.g., control circuitry 1434) and/or generate displays. Computing device 1402 may receive the displays generated by the remote server and may display the content of the displays locally via display 1410. For example, display 1410 may be utilized to present a string of characters. This way, the processing of the instructions is performed remotely (e.g., by server 1404) while the resulting displays, such as the display windows described elsewhere herein, are provided locally on computing device 1404. Computing device 1402 may receive inputs from the user via input/output circuitry 1412 and transmit those inputs to the remote server for processing and generating the corresponding displays.

Alternatively, computing device 1402 may receive inputs from the user via input/output circuitry 1412 and process and display the received inputs locally, by control circuitry 1408 and display 1410, respectively. For example, input/output circuitry 1412 may correspond to a keyboard and/or a set of and/or one or more speakers/microphones which are used to receive user inputs (e.g., input as displayed in a search bar or a display of FIG. 14 on a computing device). Input/output circuitry 1412 may also correspond to a communication link between display 1410 and control circuitry 1408 such that display 1410 updates based at least in part on inputs received via input/output circuitry 1412 (e.g., simultaneously update what is shown in display 1410 based on inputs received by generating corresponding outputs based on instructions stored in memory via a non-transitory, computer-readable medium).

Server 1404 and computing device 1402 may transmit and receive content and data such as media content via communication network 1406. For example, server 1404 may be a media content provider, and computing device 1402 may be a smart television configured to download or stream media content, such as a live news broadcast, from server 1404. Control circuitry 1434, 1408 may send and receive commands, requests, and other suitable data through communication network 1406 using communication circuitry 1432, 1426, respectively. Alternatively, control circuitry 1434, 1408 may communicate directly with each other using communication circuitry 1432, 1426, respectively, avoiding communication network 1406.

It is understood that computing device 1402 is not limited to the embodiments and methods shown and described herein. In nonlimiting examples, computing device 1402 may be a television, a Smart TV, a set-top box, an integrated receiver decoder (IRD) for handling satellite television, a digital storage device, a digital media receiver (DMR), a digital media adapter (DMA), a streaming media device, a DVD player, a DVD recorder, a connected DVD, a local media server, a BLU-RAY player, a BLU-RAY recorder, a personal computer (PC), a laptop computer, a tablet computer, a WebTV box, a personal computer television (PC/TV), a PC media server, a PC media center, a handheld computer, a stationary telephone, a personal digital assistant (PDA), a mobile telephone, a portable video player, a portable music player, a portable gaming machine, a smartphone, or any other device, computing equipment, or wireless device, and/or combination of the same, capable of suitably displaying and manipulating media content.

Computing device 1402 receives user input 1414 at input/output circuitry 1412. For example, computing device 1402 may receive a user input such as a user swipe or user touch. It is understood that computing device 1402 is not limited to the embodiments and methods shown and described herein.

User input 1414 may be received from a user selection-capturing interface that is separate from device 1402, such as a remote-control device, trackpad, or any other suitable user movement-sensitive, audio-sensitive or capture devices, or as part of device 1402, such as a touchscreen of display 1410. Transmission of user input 1414 to computing device 1402 may be accomplished using a wired connection, such as an audio cable, USB cable, ethernet cable and the like attached to a corresponding input port at a local device, or may be accomplished using a wireless connection, such as Bluetooth, Wi-Fi, WiMAX, GSM, UTMS, CDMA, TDMA, 8G, 4G, 4G LTE, 5G, NearLink, ultra-wideband technology, or any other suitable wireless transmission protocol. Input/output circuitry 1412 may include a physical input port such as a 12.5 mm (0.4921 inch) audio jack, RCA audio jack, USB port, ethernet port, or any other suitable connection for receiving audio over a wired connection or may include a wireless receiver configured to receive data via Bluetooth, Wi-Fi, WiMAX, GSM, UTMS, CDMA, TDMA, 3G, 4G, 4G LTE, 5G, NearLink, ultra-wideband technology, or other wireless transmission protocols.

Processing circuitry 1418 may receive user input 1414 from input/output circuitry 1412 using communication path 1416. Processing circuitry 1418 may convert or translate the received user input 1414 that may be in the form of audio data, visual data, gestures, or movement to digital signals. In some embodiments, input/output circuitry 1412 performs the translation to digital signals. In some embodiments, processing circuitry 1418 (or processing circuitry 1436, as the case may be) conducts disclosed processes and methods.

Processing circuitry 1418 may provide requests to storage 1421 by communication path 1420. Storage 1421 may provide requested information to processing circuitry 1418 by communication path 1446. Storage 1421 may transfer a request for information to communication circuitry 1426 which may translate or encode the request for information to a format receivable by communication network 1406 before transferring the request for information by communication path 1428. Communication network 1406 may forward the translated or encoded request for information to communication circuitry 1432, by communication path 1430.

At communication circuitry 1432, the translated or encoded request for information, received through communication path 1430, is translated or decoded for processing circuitry 1436, which will provide a response to the request for information based on information available through control circuitry 1434 or storage 1438, or a combination thereof. The response to the request for information is then provided back to communication network 1406 by communication path 1440 in an encoded or translated format such that communication network 1406 forwards the encoded or translated response back to communication circuitry 1426 by communication path 1442.

At communication circuitry 1426, the encoded or translated response to the request for information may be provided directly back to processing circuitry 1418 by communication path 1454 or may be provided to storage 1421 through communication path 1444, which then provides the information to processing circuitry 1418 by communication path 1446. Processing circuitry 1418 may also provide a request for information directly to communication circuitry 1426 through communication path 1452, where storage 1421 responds to an information request (provided through communication path 1420 or 1444) by communication path 1424 or 1446 that storage 1421 does not contain information pertaining to the request from processing circuitry 1418.

Processing circuitry 1418 may process the response to the request received through communication paths 1446 or 1454 and may provide instructions to display 1410 for a notification to be provided to the users through communication path 1448. Display 1410 may incorporate a timer for providing the notification or may rely on inputs through input/output circuitry 1412 from the user, which are forwarded through processing circuitry 1418 through communication path 1448, to determine how long or in what format to provide the notification. When display 1410 determines the display has been completed, a notification may be provided to processing circuitry 1418 through communication path 1450.

The communication paths provided in FIG. 14 between computing device 1402, server 1404, communication network 1406, and all subcomponents depicted are examples and may be modified to reduce processing time or enhance processing capabilities for each step in the processes disclosed herein by one skilled in the art.

### Terminology

The terminology used herein is for the purpose of describing particular embodiments only and is not intended to be limiting of the disclosure.

Throughout the specification the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises.”

Throughout the specification the phrases “in response to” and “based on” shall be understood to have a broad meaning unless context requires otherwise. For example, “in response to” can refer to a step that is in direct or indirect response to a prior step, and “based on” can refer to a step that is based at least in part on a prior step.

As used herein, the terms “real time,” “simultaneous,” “substantially on-demand,” and the like are understood to be nearly instantaneous but may include delay due to practical limits of the system. Such delays may be in the order of milliseconds or microseconds, depending on the application and nature of the processing. Relatively longer delays (e.g., greater than a millisecond) may result due to communication or processing delays, particularly in remote and cloud computing environments.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Although at least some embodiments are described as using a plurality of units or modules to perform a process or processes, it is understood that the process or processes may also be performed by one or a plurality of units or modules. Additionally, it is understood that the term controller/control unit may refer to a hardware device that includes a memory and a processor. The memory may be configured to store the units or the modules, and the processor may be specifically configured to execute said units or modules to perform one or more processes which are described herein.

Unless specifically stated or obvious from context, as used herein, the term “about” is understood as within a range of normal tolerance in the art, for example within 2 standard deviations of the mean. “About” may be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

The use of the terms “first”, “second”, “third”, and so on, herein, are provided to identify structures or operations, without describing an order of structures or operations, and, to the extent the structures or operations are used in an embodiment, the structures may be provided or the operations may be executed in a different order from the stated order unless a specific order is definitely specified in the context.

The methods and/or any instructions for performing any of the embodiments discussed herein may be encoded on computer-readable media. Computer-readable media includes any media capable of storing data. The computer-readable media may be transitory, including, but not limited to, propagating electrical or electromagnetic signals, or may be non-transitory (e.g., a non-transitory, computer-readable medium accessible by an application via control or processing circuitry from storage) including, but not limited to, volatile and non-volatile computer memory or storage devices such as a hard disk, floppy disk, USB drive, DVD, CD, media cards, register memory, processor caches, random access memory (RAM), UltraRAM, cloud-based storage, and the like.

The interfaces, processes, and analysis described may, in some embodiments, be performed by an application. The application may be loaded directly onto each device of any of the systems described or may be stored in a remote server or any memory and processing circuitry accessible to each device in the system. The generation of interfaces and analysis there-behind may be performed at a receiving device, a sending device, or some device or processor therebetween.

Any use of a phrase such as “in some embodiments” or the like with reference to a feature is not intended to link the feature to another feature described using the same or a similar phrase. Any and all embodiments disclosed herein are combinable or separately practiced as appropriate. Absence of the phrase “in some embodiments” does not infer that the feature is necessary. Inclusion of the phrase “in some embodiments” does not infer that the feature is not applicable to other embodiments or even all embodiments.

The systems and processes discussed herein are intended to be illustrative and not limiting. One skilled in the art would appreciate that the actions of the processes discussed herein may be omitted, modified, combined, duplicated, rearranged, and/or substituted, and any additional actions may be performed without departing from the scope of the invention. More generally, the disclosure herein is meant to provide examples and is not limiting. Only the claims that follow are meant to set bounds as to what the present disclosure includes. Furthermore, it should be noted that the features and limitations described in any some embodiments may be applied to any other embodiment herein, and flowcharts or examples relating to some embodiments may be combined with any other embodiment in a suitable manner, done in different orders, or done in parallel. In addition, the methods and systems described herein may be performed in real time. It should also be noted that the methods and/or systems described herein may be applied to, or used in accordance with, other methods and/or systems.

This description is to be taken only by way of example and not to otherwise limit the scope of the embodiments herein. Therefore, it is the object of the appended claims to cover all such variations and modifications as come within the true spirit and scope of the embodiments herein.

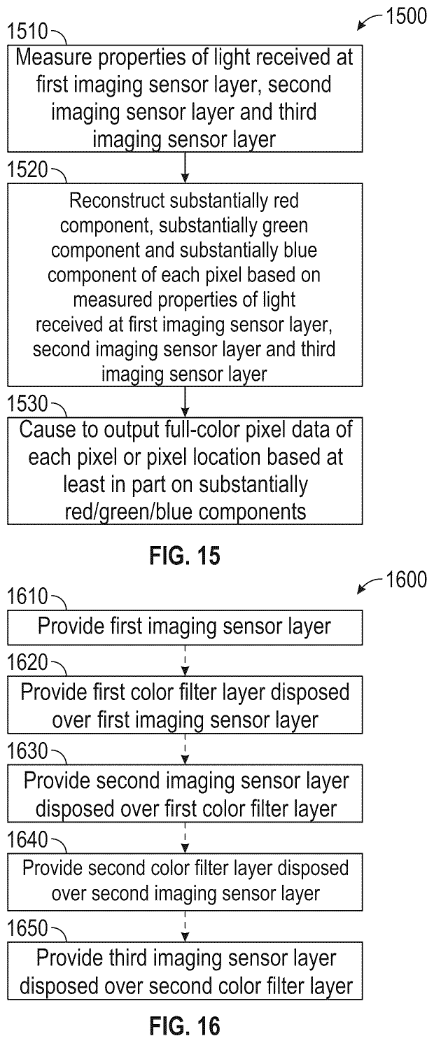

FIG. 15 is a flowchart of the process for capturing an image with an image sensor operatively connected to control circuitry, in accordance with some embodiments of the disclosure. In various embodiments, the individual steps of process 1500 may be implemented by one or more components of the devices and software of FIGS. 1-7, 9-14 and 19-22. Although the present disclosure may describe certain steps of process 1500 (and of other processes described herein) as being implemented by certain components of the devices and software of FIGS. 1-7, 9-14 and 19-22, this is for purposes of illustration only, and it should be understood that other components of the devices and systems of FIGS. 1-7, 9-14 and 19-22 may implement those steps instead.

Process 1500 begins at step 1510, where control circuitry (e.g., the control circuitry of camera device 100 as further described in relation to FIGS. 1-2B) measures the properties of the light transmitted to a first imaging sensor layer, a second imaging sensor layer and third imaging sensor layer. In some approaches, the first imaging sensor layer, the second imaging sensor layer and the third imaging sensor layer are first imaging sensor layer 310, second imaging sensor layer 330 and third imaging sensor layer 350 of FIG. 3, or first imaging sensor layer 910, second imaging sensor layer 930 and third image sensor layer 950 of FIGS. 9 and 10. In some implementations, the imaging sensor layers are any of the imaging sensor layers as further described in relation to FIGS. 4-13F.

At step 1520, the control circuitry reconstructs a substantially red component, a substantially green component, and a substantially blue component of each pixel of an image sensed by the image sensor. Also, for example, the control circuitry reconstructs the red, green, and blue components of each pixel for output to a display. Further, for example, the components are based on these measurements and/or a predetermined transmittance rate of each image sensor layer and/or each color filter layer. Still further, for example, the control circuitry then outputs these full-color components for each pixel or pixel location. In some embodiments, the method of reconstructing the R, G and B light components in full resolution is performed in any way as further described in relation to FIGS. 1-13F. In some approaches, the substantially red component, the substantially green component, and the substantially blue component of each pixel are the R (i.e., red), G (i.e., green) and B (i.e., blue) components of light as further described in relation to FIGS. 1-13F.

At step 1530, the substantially red component, the substantially green component, and the substantially blue component of each pixel are output and displayed to a user via interface circuitry. For example, a resulting image is moved to a file storage location, and/or transmitted to a remote storage location. In some embodiments, interface circuitry is interface circuitry 140 of FIG. 1, image interface 730 of FIG. 7, or the user interface as described in relation to FIG. 14.

FIG. 16 is a flowchart of the process for manufacturing an image sensor, in accordance with some embodiments of the disclosure. In various embodiments, the individual steps of process 1600 may be implemented by one or more components of the devices and software of FIGS. 1-7, 9-14 and 19-22. Although the present disclosure may describe certain steps of process 1600 (and of other processes described herein) as being implemented by certain components of the devices and software of FIGS. 1-7, 9-14 and 19-22, this is for purposes of illustration only, and it should be understood that other components of the devices and systems of FIGS. 1-7, 9-14 and 19-22 may implement those steps instead.

Process 1600 begins at step 1610, where a first imaging sensor is provided. In some embodiments, the first imaging sensor is first imaging sensor layer 310 of FIG. 3 or first imaging sensor layer 910 of FIGS. 9 and 10.

At step 1620, a first color filter layer is placed over the first imaging layer. In some approaches, the first color filter layer is first color filter layer 320 of FIG. 3 or first color filter layer 920 of FIGS. 9 and 10.

At step 1630, a second imaging sensor layer is placed over the first color filter layer. In some implementations, the second imaging sensor layer is second imaging sensor layer 330 of FIG. 3 or second imaging sensor layer 930 of FIGS. 9 and 10.

At step 1640, a second color filter layer is placed over the second imaging sensor layer. In some embodiments, the second color filter layer is second color filter 340 of FIG. 3 or second color filter layer 940 of FIGS. 9 and 10.

At step 1650, a third imaging sensor layer is placed over the second color filter layer. In some approaches, the third imaging sensor layer is third imaging sensor layer 350 of FIG. 3 or third image sensor layer 950 of FIG. 9.

Each imaging sensor layer and each color filter layer sandwiched in-between the imaging sensor layers is aligned with and attached to the immediately adjacent layer to form the stacked sensor configuration. Each layer is attached to a different layer using any of the manufacturing techniques further described in relation to FIG. 10.

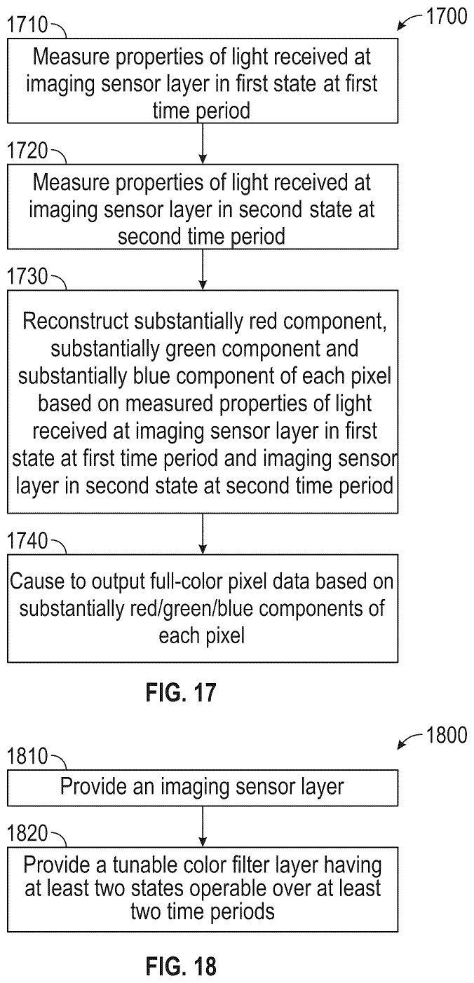

FIG. 17 is a flowchart of the process for capturing an image with an image sensor utilizing a tunable color filter, in accordance with some embodiments of the disclosure. In various embodiments, the individual steps of process 1700 may be implemented by one or more components of the devices and software of FIGS. 1-7, 9-14 and 19-22. Although the present disclosure may describe certain steps of process 1700 (and of other processes described herein) as being implemented by certain components of the devices and software of FIGS. 1-17, this is for purposes of illustration only, and it should be understood that other components of the devices and systems of FIGS. 1-16 may implement those steps instead.

Process 1700 begins at step 1710, where a control circuitry (e.g., the control circuitry of camera device 100 as further described in relation to FIGS. 1-2B) measures the properties of the light transmitted to an imaging sensor layer in a first state of at least two states, at a first period of at least two time periods. For example, an imaging sensor layer in a first state may be configured to detect only (R+G) components, as shown in FIG. 11A. In some embodiments, the light transmission properties indicate the amount of incident light that can be transmitted to an image sensor at specific wavelengths, as further described in relation to FIG. 3. In some approaches, the imaging sensor layer is any imaging sensor layer as further described in FIGS. 4-6 and 11A-13F.

At step 1720, the control circuitry measures the properties of the light transmitted to the imaging sensor layer in a second state of at least two states, at a second time period of at least two time periods. For example, an imaging sensor layer in a second state may be configured to detect only green light components, as shown in FIG. 11B.

At step 1730, the control circuitry reconstructs a substantially red component, a substantially green component, and a substantially blue component of each pixel of a display based on the measured properties of light transmitted to the first imaging sensor layer in the first state at the first time period and the second imaging sensor layer in the second state at the second time period. In some embodiments, the method of reconstructing the R, G and B light components in full resolution is performed in any way as further described in relation to FIGS. 1-13F. In some approaches, the substantially red component, the substantially green component, and the substantially blue component of each pixel are the R (i.e., red), G (i.e., green) and B (i.e., blue) components of light as further described in relation to FIGS. 1-13F.

At step 1740, the substantially red component, the substantially green component, and the substantially blue component of each pixel or pixel location are output and may be displayed to a user via interface circuitry. In some embodiments, interface circuitry is interface circuitry 140 of FIG. 1, image interface 730 of FIG. 7, or the user interface as described in FIG. 14.

FIG. 18 is a flowchart of the process for manufacturing an image sensor with a tunable color filter, in accordance with some embodiments of the disclosure. In various embodiments, the individual steps of process 1800 may be implemented by one or more components of the devices and software of FIGS. 1-7, 9-14 and 19-22. Although the present disclosure may describe certain steps of process 1800 (and of other processes described herein) as being implemented by certain components of the devices and software of FIGS. 1-7, 9-14 and 19-22, this is for purposes of illustration only, and it should be understood that other components of the devices and systems of FIGS. 1-7, 9-14 and 19-22 may implement those steps instead.

Process 1800 begins at step 1810, where at least one imaging sensor layer is provided. In some approaches, the imaging sensor layer is any imaging sensor layer as further described in FIGS. 4-6 and 11A-13F.

At step 1820, at least one tunable color filter layer having at least two states operable over at least two time periods is provided. In some implementations, the tunable color filter layer is any tunable color filter layer as further described in FIGS. 3-6 and 11A-13F.

Each imaging sensor layer and each color filter layer is aligned with and attached to the immediately adjacent layer to form the stacked sensor configuration. Each layer is attached to a different layer using any of the manufacturing techniques further described in relation to FIG. 10.

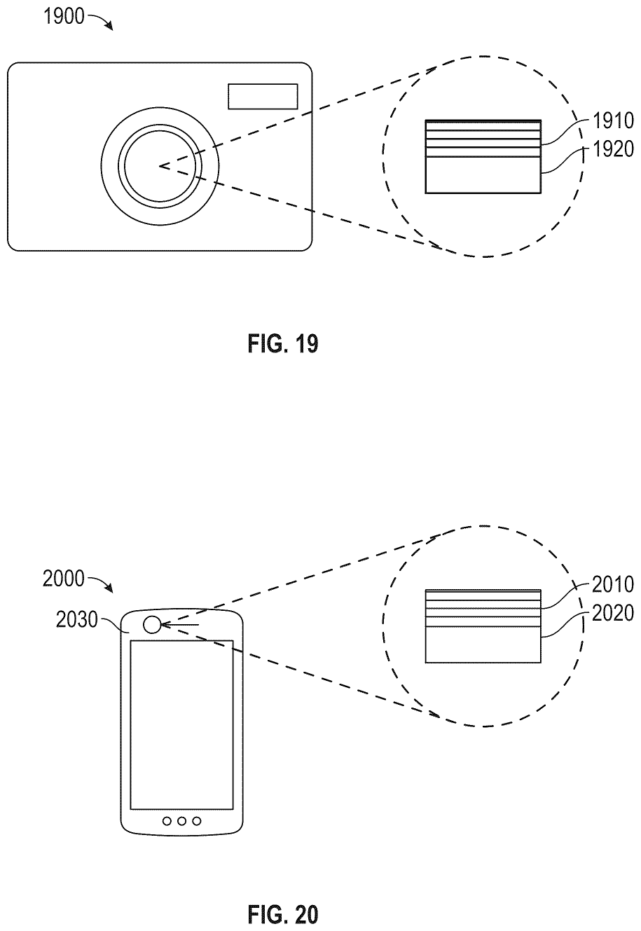

FIG. 19 depicts a diagram of a camera device utilizing a static (e.g., as shown in FIG. 3 or 9) or tunable (e.g., as shown in any one of FIGS. 4-6 and 11-13) color filter, in accordance with some embodiments of the disclosure.

In some embodiments, camera device 1900 is camera device 100 as described in relation to FIGS. 1-2B. Camera device 1900 utilizes an image sensor that is configured to detect light funneled through a lens or some other optics. In some approaches, the image sensor is image sensor 200 of FIGS. 1-2A. The image sensor of camera device 1900 contains a plurality of pixels that are each capable of receiving all color components of incident white light. The image sensor includes a sensor area including a plurality of pixels. For example, the image sensor comprises at least one imaging sensor layer 1920 and at least one tunable color filter 1910 configured to switch between at least two different color states at two or more time periods in order to filter the various components of incident white light. In some implementations, a sensor arrangement (e.g., including layer 1920 and filter 1910) may be replaced with any other stacked arrangement, including those as previously described in relation to FIGS. 3-13F. In some embodiments, tunable color filter layer 1910 is any tunable color filter layer as further described in FIGS. 3-6 and 11A-13F. Like the tunable color filter layers of FIGS. 3-6 and 11A-13F, tunable color filter layer 1910 is configured to filter the various components of white light in a time-multiplexed manner, by switching between different color states at different time periods.

In some approaches, imaging sensor layer 1920 and tunable color filter 1910 are assembled and attached to each other in any manner as described in relation to FIG. 10.

In some implementations, once all components of white light have been received by imaging sensor layer 1920 and processed, camera device 1900 begins to reconstruct the light components, detected at each pixel, in full resolution. In some embodiments, the method of reconstructing the R, G and B light components in full resolution is performed in any way as contemplated in relation to FIGS. 1-13F.

FIG. 20 depicts a diagram of a smartphone with a camera utilizing a static (e.g., as shown in FIG. 3 or 9) or tunable (e.g., as shown in any one of FIGS. 4-6 and 11-13) color filter, in accordance with some embodiments of the disclosure.

In some embodiments, smartphone 2000 comprises various hardware components, including camera component 2030. Camera component 2030 is configured to capture real-world images using the functions provided by smartphone 2000. Camera component 2030 utilizes an image sensor that is configured to detect light funneled through a lens or some other optics. In some approaches, the image sensor is image sensor 200 of FIGS. 1-2A. The image sensor of camera component 2030 contains a plurality of pixels that are each capable of receiving all color components of incident white light. Each pixel of the image sensor is equipped with a stacked sensor comprising at least one imaging sensor layer 2020 and at least one tunable color filter 2010 configured to switch between at least two different color states at two or more time periods in order to filter the various components of incident white light. In some implementations, imaging sensor layer 2020 is any imaging sensor layer as previously described in relation to FIGS. 3-13F. In some embodiments, tunable color filter layer 2010 is any tunable color filter layer as further described in relation to FIGS. 3-6 and 11A-13F. Like the tunable color filter layers of FIGS. 3-6 and 11A-13F, tunable color filter layer 2010 is configured to filter the various components of white light in a time-multiplexed manner, by switching between different color states at different time periods.

In some approaches, imaging sensor layer 2020 and tunable color filter 2010 are assembled and attached to each other in any manner as described in relation to FIG. 10.

In some implementations, once all components of white light have been received by imaging sensor layer 2020 and processed, camera component 2030 begins to reconstruct the light components, detected at each pixel, in full resolution. In some embodiments, the method of reconstructing the R, G and B light components in full resolution is performed in any way as contemplated by FIGS. 1-13F.

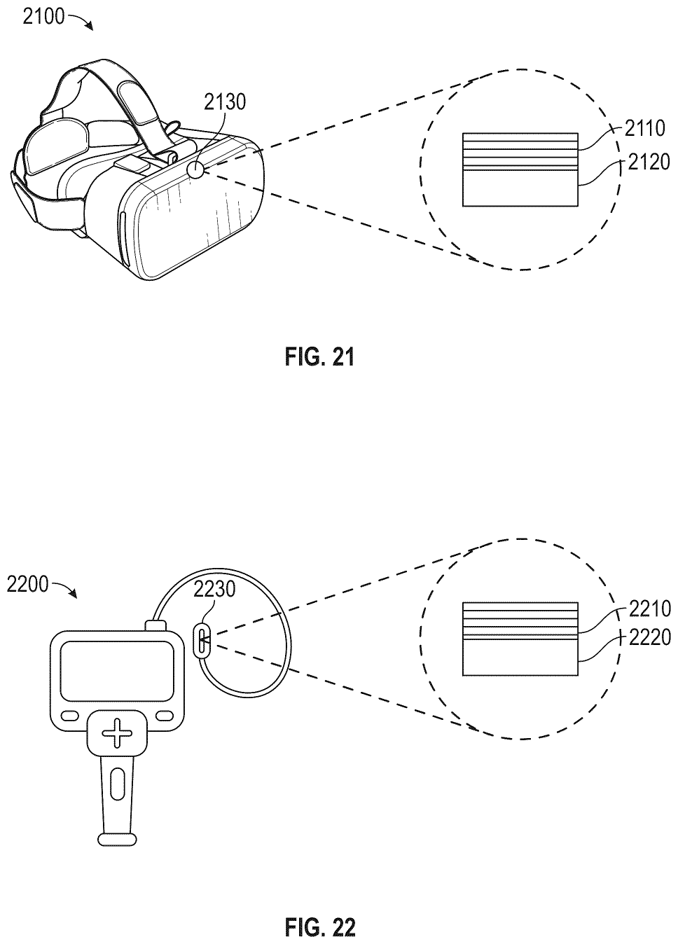

FIG. 21 depicts a diagram of an extended reality device utilizing a static (e.g., as shown in FIG. 3 or 9) or tunable (e.g., as shown in any one of FIGS. 4-6 and 11-13) color filter, in accordance with some embodiments of the disclosure.

In some embodiments, extended reality device 2100 comprises various hardware components, including camera component 2130. Camera component 2130 is configured to capture real-world images using the functions provided by extended reality device 2100. Camera component 2130 utilizes an image sensor that is configured to detect light funneled through a lens or some other optics. In some approaches, the image sensor is image sensor 200 of FIGS. 1-2A. The image sensor of camera component 2130 contains a plurality of pixels that are each capable of receiving all color components of incident white light. Each pixel of the image sensor is equipped with a stacked sensor comprising at least one imaging sensor layer 2120 and at least one tunable color filter 2110 configured to switch between at least two different color states at two or more time periods in order to filter the various components of incident white light. In some implementations, imaging sensor layer 2120 is any imaging sensor layer as previously described in relation to FIGS. 3-13F. In some embodiments, tunable color filter layer 2110 is any tunable color filter layer as further described in relation to FIGS. 3-6 and 11A-13F. Like the tunable color filter layers of FIGS. 3-6 and 11A-13F, tunable color filter layer 2110 is configured to filter the various components of white light in a time-multiplexed manner, by switching between different color states at different time periods.

In some approaches, imaging sensor layer 2120 and tunable color filter 2110 are assembled and attached to each other in any manner as described in relation to FIG. 10.

In some implementations, once all components of white light have been received by imaging sensor layer 2120 and processed, camera component 2130 begins to reconstruct the light components, detected at each pixel, in full resolution. In some embodiments, the method of reconstructing the R, G and B light components in full resolution is performed in any way as contemplated by FIGS. 1-13F.

FIG. 22 depicts a diagram of a medical imaging device utilizing a static (e.g., as shown in FIG. 3 or 9) or tunable (e.g., as shown in any one of FIGS. 4-6 and 11-13) color filter, in accordance with some embodiments of the disclosure.

In some embodiments, medical imaging device 2200 comprises various hardware components, including camera component 2230. Camera component 2230 is configured to capture real-world images using the functions provided by medical imaging device 2200. Camera component 2230 utilizes an image sensor that is configured to detect light funneled through a lens or some other optics. In some approaches, the image sensor is image sensor 200 of FIGS. 1-2A. The image sensor of camera component 2230 contains a plurality of pixels that are each capable of receiving all dominant color components of incident white light. In some embodiments, dominant wavelengths of incident light include ultraviolet (UV), X-Rays and infrared (IR). Each pixel of the image sensor is equipped with a stacked sensor comprising at least one imaging sensor layer 2220 and at least one tunable color filter 2210 configured to switch between at least two different color states at two or more time periods in order to filter the various components of incident white light. In some implementations, imaging sensor layer 2220 is any imaging sensor layer as previously described in relation to FIGS. 3-13F. In some embodiments, tunable color filter layer 2210 is any tunable color filter layer as further described in relation to FIGS. 3-6 and 11A-13F. Like the tunable color filter layers of FIGS. 3-6 and 11A-13F, tunable color filter layer 2210 is configured to filter the various components of white light in a time-multiplexed manner, by switching between different color states at different time periods.

In some approaches, imaging sensor layer 2220 and tunable color filter 2210 are assembled and attached to each other in any manner as described in relation to FIG. 10.

In some implementations, once all components of white light have been received by imaging sensor layer 2220 and processed, camera component 2230 begins to reconstruct the light components, detected at each pixel, in full resolution. In some embodiments, the method of reconstructing the R, G and B light components in full resolution is performed in any way as contemplated by FIGS. 1-13F.

1. An image sensor comprising:
a first imaging sensor layer;
a first color filter layer disposed over the first imaging sensor layer;
a second imaging sensor layer disposed over the first color filter layer, wherein the second imaging sensor layer is substantially transparent;
a second color filter layer disposed over the second imaging sensor layer; and
a third imaging sensor layer disposed over the second color filter layer, wherein the third imaging sensor layer is substantially transparent.

2. The image sensor of claim 1, wherein:
the first color filter layer allows a first range of wavelengths of light to substantially pass therethrough, and
the second color filter layer allows the first range of wavelengths of light and a second range of wavelengths of light to substantially pass therethrough.

3. The image sensor of claim 1, wherein the first color filter layer allows substantially green light to pass therethrough.

4. The image sensor of claim 1, wherein the second color filter layer allows substantially red light to pass therethrough.

5. The image sensor of claim 1, wherein:
the first color filter layer substantially blocks a first range of wavelengths of light from passing therethrough, and
the second color filter layer substantially blocks a second range of wavelengths of light from passing therethrough.

6. The image sensor of claim 1, wherein the first color filter layer blocks substantially red light from passing therethrough.

7. The image sensor of claim 1, wherein the first color filter layer substantially blocks light above a wavelength of about 610 nm from passing therethrough.

8. The image sensor of claim 1, wherein the second color filter layer blocks substantially blue light from passing therethrough.

9. The image sensor of claim 1, wherein the second color filter layer substantially blocks light below a wavelength of about 520 nm from passing therethrough.

10.-22. (canceled)

23. A method of capturing an image with an image sensor operatively connected to control circuitry, wherein:
the image sensor comprises:
a first imaging sensor layer;
a first color filter layer disposed over the first imaging sensor layer;
a second imaging sensor layer disposed over the first color filter layer, wherein the second imaging sensor layer is substantially transparent;
a second color filter layer disposed over the second imaging sensor layer; and
a third imaging sensor layer disposed over the second color filter layer, wherein the third imaging sensor layer is substantially transparent; and
the method comprises:
measuring, at the control circuitry, properties of light received at the first imaging sensor layer, the second imaging sensor layer, and the third imaging sensor layer;
reconstructing, at the control circuitry, a substantially red component, a substan-tially green component, and a substantially blue component of each pixel based at least in part on the measured properties of light received at the first imaging sensor layer, the second imaging sensor layer, and the third imaging sensor layer; and
causing to be output full-color pixel data of each pixel or pixel location based at least in part on the substantially red component, the substantially green component, and the sub-stantially blue component.

24. The method of claim 23, wherein:
the first color filter layer substantially allows a first range of wavelengths of light to pass therethrough, and
the second color filter layer substantially allows the first range of wavelengths of light and a second range of wavelengths of light to pass therethrough.

25. The method of claim 23, wherein the first color filter layer allows substantially green light to pass therethrough.

26. The method of claim 23, wherein the second color filter layer allows substantially red light to pass therethrough.

27. The method of claim 23, wherein:
the first color filter layer substantially blocks a first range of wavelengths of light from passing therethrough, and
the second color filter layer substantially blocks a second range of wavelengths of light from passing therethrough.

28. The method of claim 23, wherein the first color filter layer blocks substantially red light from passing therethrough.

29. The method of claim 23, wherein the first color filter layer blocks light above a wavelength of about 610 nm from passing therethrough.

30. The method of claim 23, wherein the second color filter layer blocks substantially blue light from passing therethrough.

31. The method of claim 23, wherein the second color filter layer blocks light below a wavelength of about 520 nm from passing therethrough.

32.-108. (canceled)

109. An image sensor comprising:
a first transparent sensor layer;
a first color filter layer;
a second transparent sensor layer; and
a second color filter layer,
wherein the first transparent sensor layer, the first color filter layer, the second transparent sensor layer, and the second color filter layer are provided in a stack.

110. The image sensor of claim 109, wherein:
the first color filter layer substantially allows a first range of wavelengths of light to pass therethrough, and
the second color filter layer substantially allows the first range of wavelengths of light and a second range of wavelengths of light to pass therethrough.

111.-204. (canceled)
